(19) United States
(12) Patent Application Publication
(10) Pub. No.: US 2024/0250528 A1
(43) Pub. Date: Jul. 25, 2024

(54) METHODS AND SYSTEMS FOR CONTROLLING MULTI-STAGE VOLTAGE SAGS

(71) Applicant: SICHUAN UNIVERSITY, Chengdu (CN)

(72) Inventors: Ying WANG, Chengdu (CN); Haishan HE, Chengdu (CN); Xianyong XIAO, Chengdu (CN); Wenxi HU, Chengdu (CN); Yunzhu CHEN, Chengdu (CN)

(21) Appl. No.: 18/622,847

(22) Filed: Mar. 29, 2024

Related U.S. Application Data
(63) Continuation-in-part of application No. 18/082,611, filed on Dec. 16, 2022, now abandoned.

(30) Foreign Application Priority Data
Mar. 3, 2022 (CN) 202210201077.X

(51) Int. Cl. H02J 3/00; G01R 31/08; G06F 17/16; H02J 13/00

(52) U.S. Cl. CPC H02J 3/0012; G01R 31/086; G01R 31/088; H02J 13/00001; H02J 13/00002; H02J 13/00007; H02J 13/0004; G06F 17/16

(57) ABSTRACT

Disclosed is a system and a method for controlling a multi-stage voltage sag. The system includes a power quality monitoring device with a processor, a voltage sag analysis device, a voltage sag data storage device, and an early warning device. The power quality monitoring device is configured to read voltage sag data and fault clearing information and send the voltage sag data to a power terminal device. The voltage sag analysis device is configured to determine a cause of the multi-stage voltage sag at different grid locations; determine an updated value of a fault clearing time of a relay protection device and retrofit location information of an electric power stabilizing device; control a corresponding relay protection device to adjust a count of capacitors and types of the capacitors to be connected to a circuit; and issue an early warning notification of retrofitting the electric power stabilizing device to a user.

### CROSS-REFERENCE TO RELATED APPLICATIONS

This application is a continuation-in-part of U.S. application Ser. No. 18/082,611, filed on Dec. 16, 2022, which claims priority of Chinese Application No. 202210201077.X, filed on Mar. 3, 2022, the entire contents of each of which are incorporated herein by reference.

### TECHNICAL FIELD

The present disclosure relates to a field of voltage sag control, and in particular to a method and a system for controlling a multi-stage voltage sag.

### BACKGROUND

Currently, methods for controlling voltage sags mainly focus on single-stage rectangular sags caused by short circuits, lacking methods suitable for controlling multi-stage voltage sags. However, a frequency of multi-stage voltage sag events is gradually increasing, and the problem of multi-stage sags cannot be ignored. For example, with the development of new power systems, a proportion of distributed generation devices connected to the power systems is increasing. During a short circuit fault, a sag may cause a single distributed generation device to trip or multiple distributed generation devices to trip in cascade, forming a complex multi-stage sag. In addition, commonly used staged protections in the power systems, such as distance protection, may also cause multi-stage sags due to its operating characteristics.

The voltage sag is the most severe disturbance affecting sensitive devices and cannot be avoided. The Institute of Electrical and Electronics Engineers defines voltage sag as a power quality phenomenon where an effective value of a supply voltage rapidly drops to 0.1 to 0.9 per unit (p. u.), lasting from 0.5 cycles to 1 minute. To address voltage sag issues, it is essential to accurately reflect voltage sag levels at different locations in the power system, thus requiring the installation of necessary monitoring devices for sag monitoring. Due to the large and complex nature of a power grid, the monitoring devices can typically only be installed at some bus lines in consideration of monitoring costs and information processing capabilities. Estimating the sag levels (mainly referring to sag magnitude and duration of voltage sags) of unmonitored bus lines (i.e., bus lines without monitoring devices installed) using limited monitoring data is an important research task. With the gradual increase in the frequency of multi-stage voltage sags, proposing a suitable method for controlling a multi-stage voltage sag is of significant importance.

The main challenges in multi-stage voltage sag control are as follows: A main cause of the multi-stage voltage sag is disconnection of distributed generation device(s) or protection devices at two ends of a line tripping at different times during a short circuit. A first challenge is how to determine the cause of voltage sags in different stages. A location of the short circuit is an important factor affecting a voltage magnitude. A second challenge is how to preliminarily classify possible sets of fault lines to reduce a computational load of Multi-stage Voltage Sag State Estimation (MVSSE). During the short circuit, the voltage magnitude at the same fault location is also influenced by events such as a count of distributed generation devices disconnected from the grid and a sequence of disconnection of the distributed generation devices from the grid, and a tripping condition of the protective devices on the fault line. A third challenge is how to infer specific causes of voltage sag events in different stages to improve the accuracy of MVSSE. For different candidate fault lines, determining different potential fault levels based on the grid location level can further reduce the computational load of a processor configured in a voltage sag analysis device. Using a fault processing model, it is possible to automatically and quickly determine the true fault lines and specific fault events from a large number of candidate fault lines, providing data support for timely determination of relay protection devices that need replacement and locations requiring installation of electric power stabilizing devices. Using a location assessment model to process a graph structure can quickly and uniformly determine whether multiple locations in the grid need retrofitting of electric power stabilizing devices, greatly reducing the computational load. Considering an impact of retrofitting the electric power stabilizing devices on operating parameter(s) of existing relay protection devices, while ensuring grid stability and safe and reliable equipment operation, operational costs can be reduced.

### SUMMARY

To address the aforementioned issues, the present disclosure provides a system, a method, and a storage medium for controlling a multi-stage voltage sag. By analyzing various causes leading to the multi-stage sag, considering an abrupt transition time of each stage in multi-stage sag monitoring data and a fault clearing time of a protection device, the present disclosure deduces possible fault event types occurring at each stage of the multi-stage voltage sag, thereby achieving control of the multi-stage voltage sag to meet engineering requirements.

One or more embodiments of the present disclosure provide a system for controlling a multi-stage voltage sag. The system may include a power quality monitoring device, a voltage sag analysis device, a voltage sag data storage device, and an early warning device. The voltage sag analysis device may include a processor. The power quality monitoring device may be configured to read voltage sag data and fault clearing information based on an acquisition control instruction issued by the voltage sag analysis device and send the voltage sag data to a power terminal device via a communication line. The acquisition control instruction may include at least one of a data reading cycle, a reading position sequence, and a reading type. The communication line may include a power line carrier communication line. The fault clearing information may include at least one of a fault clearing time, a fault duration, a fault starting time, and a fault ending time. A count of the power quality monitoring device may include at least one, and the at least one power quality monitoring device may be located at at least one different grid locations, respectively. The voltage sag analysis device may be configured to determine a cause of the multi-stage voltage sag of the at least one different grid locations based on the voltage sag data of the at least one different grid locations obtained from the power terminal device. The voltage sag analysis device may be further configured to: obtain historical fault information of the at least one different grid locations based on the voltage sag data storage device; determine the at least one of the data reading cycle, the reading position sequence, and the reading type of the power quality monitoring device located at the at least one different grid locations based on the historical fault information of the at least one different grid locations and generate the acquisition control instruction; and send the acquisition control instruction to the at least one power quality monitoring device located at the at least one different grid locations. The voltage sag analysis device may be further configured to: determine, based on the fault clearing information, an updated value of a fault clearing time of a relay protection device and retrofit location information of an electric power stabilizing device; control, based on the updated value of the fault clearing time, a corresponding relay protection device via a device control instruction to adjust a count of capacitors and types of the capacitors to be connected to a circuit; and issue an early warning notification of retrofitting the electric power stabilizing device to a user through the early warning device.

One or more embodiments of the present disclosure provide method for controlling a multi-stage voltage sag. The method may be performed by a voltage sag analysis device and the method may include: controlling, based on an acquisition control instruction, a power quality monitoring device to read voltage sag data and fault clearing information, wherein the acquisition control instruction may include at least one of a data reading cycle, a reading position sequence, and a reading type, a communication line may include at least a power line carrier communication line, the fault clearing information may include at least one of a fault clearing time, a fault duration, a fault starting time, and a fault ending time, a count of the power quality monitoring device may include at least one, and the at least one power quality monitoring device may be located at at least one different grid locations, respectively, the acquisition control instruction is generated by the voltage sag analysis device based on historical fault information of the at least one different grid locations and sent to the power quality monitoring device located at the at least one different grid locations, and the historical fault information is stored in a voltage sag data storage device; determining a cause of the multi-stage voltage sag of the at least one different grid locations based on the voltage sag data of the at least one different grid locations obtained from a power terminal device; determining, based on the fault clearing information, an updated value of the fault clearing time of a relay protection device and retrofit location information of an electric power stabilizing device and controlling, based on the updated value of the fault clearing time, a corresponding relay protection device via a device control instruction to adjust a count of capacitors and types of the capacitors to be connected to a circuit; and issuing an early warning notification of retrofitting the electric power stabilizing device to a user through an early warning device.

One or more embodiments of the present disclosure provide a non-transitory computer-readable storage medium, wherein the storage medium stores one or more set of computer instructions, and when a computer reads the one or more set of computer instructions from the storage medium, the computer performs the method for controlling the multi-stage voltage sag described in the embodiments of the present disclosure.

The beneficial effects of the present disclosure may include, but are not limited to: (1) analyzing characteristics of the multi-stage voltage sag caused by different causes, utilizing the characteristics to determine the causes of abrupt changes in the voltage sag magnitude during the multi-stage sag; (2) proposing a method for calculating an action matrix for a relay protection action and a set of candidate fault lines, thereby preliminarily dividing the set of candidate fault lines based on features such as a fault clearing time of a relay protection device, effectively reducing a computational load of voltage sag state control; (3) utilizing an inherent characteristic of system impedance changes caused by different fault event types to propose a method for inferring the cause of the multi-stage voltage sag, thereby improving the accuracy of voltage sag state control; (4) based on an inference result of the cause of the multi-stage voltage sag, proposing a method for controlling the multi-stage voltage sag, thus addressing the problem that existing state control methods are difficult to apply to multi-stage sags.

### BRIEF DESCRIPTION OF THE DRAWINGS

The present disclosure will be further illustrated by way of exemplary embodiments, which will be described in detail with reference to the accompanying drawings. These embodiments are not limiting. In these embodiments, the same numbering indicates the same structure, wherein:

FIG. 1 is a schematic diagram illustrating a structure of a system for controlling a multi-stage voltage sag according to some embodiments of the present disclosure;

FIG. 2 is a flowchart illustrating an exemplary process for controlling a multi-stage voltage sag according to some embodiments of the present disclosure;

FIG. 3 is a schematic diagram illustrating an exemplary process for determining of at least one fault line and a fault event type corresponding to the at least one fault line according to some embodiments of the present disclosure;

FIG. 4 is a schematic diagram illustrating a short-circuit calculation model according to some embodiments of the present disclosure;

FIG. 5 is a schematic diagram illustrating a correction algorithm according to some embodiments of the present disclosure; and

FIG. 6 is a flowchart illustrating an exemplary process for controlling a multi-stage voltage sag according to some embodiments of the present disclosure.

### DETAILED DESCRIPTION

To provide a clearer understanding of the technical solutions of the embodiments described in the present disclosure, a brief introduction to the drawings required for the description of the embodiments will be provided below. The drawings do not represent all embodiments.

It should be understood that the terms “system,” device,” “unit,” and/or “module” used herein are a way for distinguishing different components, elements, parts, sections, or assemblies at different levels. If other words can achieve the same purpose, they may be replaced with other expressions.

As shown in the present disclosure and the claims, unless context clearly indicates otherwise, terms such as “one,” “an,” “a,” and/or “the” are not specific to singular and may also include plural. Generally, the terms “comprise,” “comprises,” “comprising” and “include,” “includes,” “including” merely indicate the inclusion of specifically identified operations and elements, and these operations and elements do not constitute an exclusive list, as methods or devices may also include other operations or elements.

When processes described as being performed in operations in the embodiments of the present disclosure are executed, unless otherwise specified, the order of the operations is interchangeable, operations may be omitted, and additional operation or operations may be included in the processes.

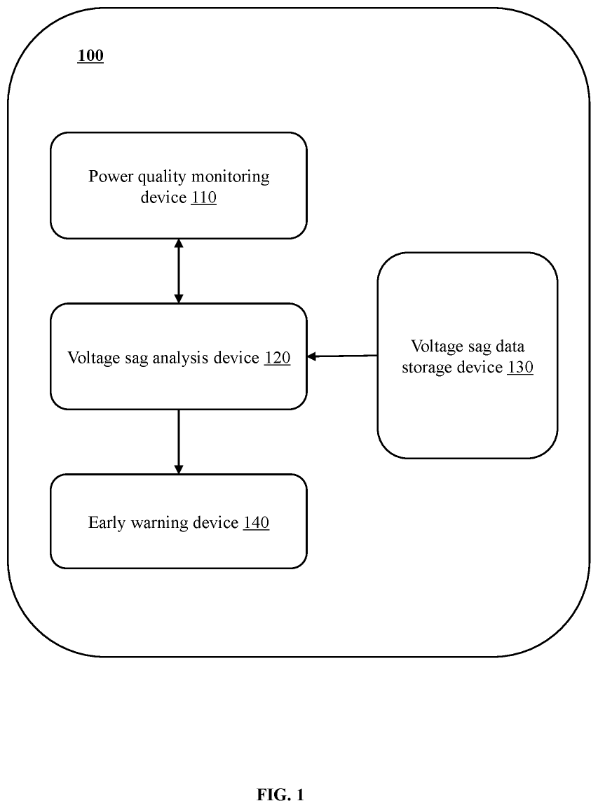

FIG. 1 is a schematic diagram illustrating a structure of a system for controlling a multi-stage voltage sag according to some embodiments of the present disclosure.

In some embodiments, a system 100 for controlling a multi-stage voltage sag (hereinafter referred to as the control system 100) may include a power quality monitoring device 110, a voltage sag analysis device 120, a voltage sag data storage device 130, and an early warning device 140.

The power quality monitoring device 110 may be configured to monitor an operation of a transmission line in a power grid. The power grid refers to a network composed of transmission lines. In some embodiments, the power quality monitoring device may include a monitoring device connected to a power terminal device for communication. For example, the power quality monitoring device may include a voltage monitoring device, a power impedance monitoring device, or the like. In some embodiments, a count of the power quality monitoring device 110 includes at least one, and the at least one power quality monitoring device may be configured to be located at at least one different grid locations. The grid location refers to a position in a grid used for installing a device or equipment to monitor the transmission lines.

The power terminal device refers to a device terminal for monitoring and managing a power system. In some embodiments, the power terminal device may include a monitoring master station. The monitoring master station may be configured to monitor and manage the entire power system.

In some embodiments, the power quality monitoring device 110 may be configured to communicate with the power terminal device through a communication line. The communication line may include a power line carrier communication line, or the like.

In some embodiments, the power quality monitoring device 110 may be configured to collect voltage sag data and fault clearing information based on an acquisition control instruction issued by the voltage sag analysis device 120 and send the voltage sag data to the power terminal device via the communication line.

In some embodiments, the voltage sag analysis device 120 may be configured to determine a cause of the multi-stage voltage sag at the at least one different grid locations obtained from the power terminal device. The voltage sag data of the at least one different grid locations refers to voltage sag data collected by at least one power quality monitoring device located at the at least one different grid locations.

In some embodiments, the voltage sag analysis device 120 may interact with the power terminal device through the communication line. For example, the voltage sag analysis device 120 may obtain the voltage sag data of the at least one different grid locations collected by the at least one power quality monitoring device 110 via the communication line.

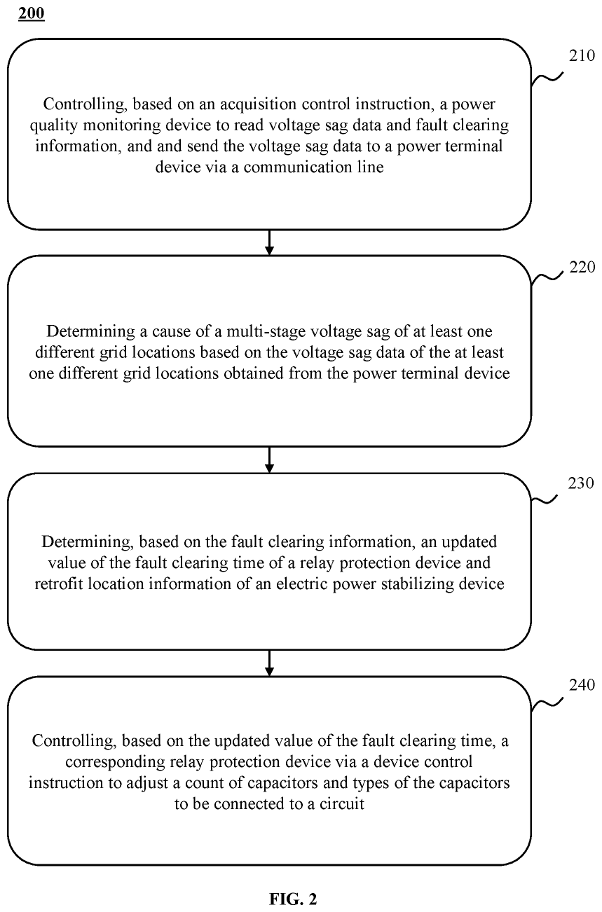

In some embodiments, the voltage sag analysis device 120 may be further configured to: determine at least one fault line based on the fault clearing information; determine, based on a voltage sag type, a fault event type corresponding to the multi-stage voltage sag occurring on the at least one fault line and generate an early warning message based on the fault event type; and issue the early warning message based on the early warning device located at the at least one different grid locations. More descriptions of this embodiment may be found in FIG. 2 and the related descriptions thereof.

In some embodiments, the voltage sag analysis device 120 may be further configured to determine magnitude data of the multi-stage voltage sag based on the fault event type and the fault clearing information and determine an updated value of a fault clearing time and retrofit location information based on the magnitude data, the at least one fault line, and the fault event type corresponding to the at least one fault line. More descriptions of this embodiment may be found in FIG. 2 and the related descriptions thereof.

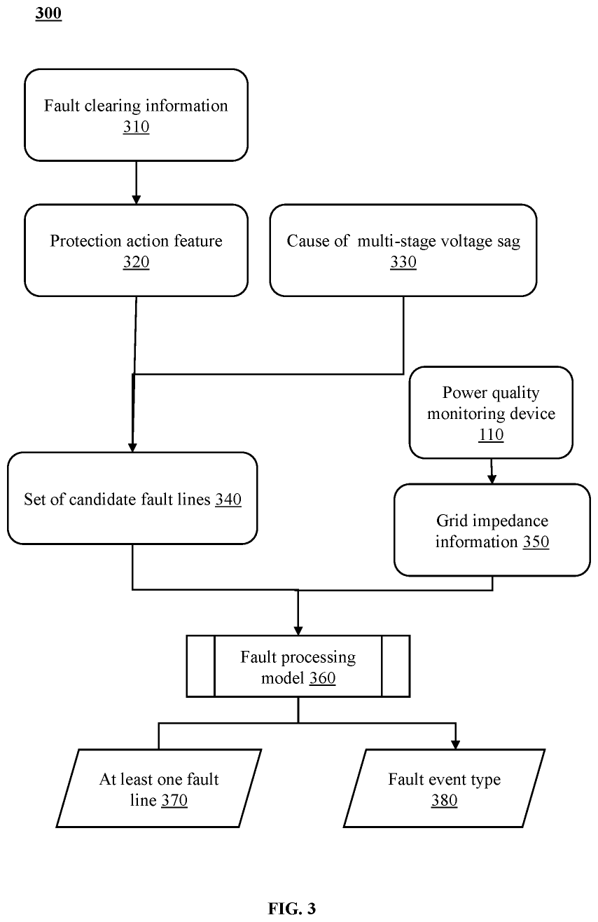

In some embodiments, the voltage sag analysis device 120 may be further configured to: determine, based on the fault clearing information, a protection action feature of the relay protection device at at least one grid location; determine a set of candidate fault lines based on the protection action feature and the cause of the multi-stage voltage sag; obtain grid impedance information through the power quality monitoring device, wherein the grid impedance information includes power system impedance information before and after the fault clearing time, impedance information at an activation time of the relay protection device, and impedance information at a disconnection time of a distributed power generation device disconnected from a grid; and determine the at least one fault line and the fault event type corresponding to the multi-stage voltage sag based on the set of candidate fault lines and the grid impedance information by using a fault processing model configured in a processor of the voltage sag analysis device. More descriptions of this embodiment may be found in FIG. 3 and the related descriptions thereof.

In some embodiments, the voltage sag analysis device 120 may be further configured to: determine an action occurrence time sequence of the relay protection device located at the at least one grid location based on the protection action feature; determine potential fault levels for different candidate fault lines based on the action occurrence time sequence; and determine the set of candidate fault lines based on the potential fault levels. More descriptions of this embodiment may be found in FIG. 3 and the related descriptions thereof.

In some embodiments, the voltage sag analysis device 120 may be further configured to: obtain historical fault information of the at least one different grid locations based on the voltage sag data storage device; determine at least one of a data reading cycle, a reading position sequence, and a reading type of the at least one power quality monitoring device located at the at least one different grid locations based on the historical fault information of the at least one different grid locations and generate the acquisition control instruction; and send the acquisition control instruction to the at least one power quality monitoring device located at the at least one different grid locations. More descriptions of this embodiment may be found in FIG. 2 and the related descriptions thereof.

In some embodiments, the voltage sag analysis device 120 may be further configured to: obtain positional data of the at least one fault line during a preset time period and construct a graph structure based on the positional data and the fault clearing information; and determine the retrofit location information by using a location assessment model configured in the processor of the voltage sag analysis device. More descriptions of this embodiment may be found in FIG. 2 and the related descriptions thereof.

In some embodiments, the voltage sag analysis device 120 may be further configured to determine the updated value of the fault clearing time based on the at least one fault line and historical fault clearing information using a preset update algorithm. More descriptions of this embodiment may be found in FIG. 2 and the related descriptions thereof.

In some embodiments, the voltage sag analysis device 120 may be further configured to determine, based on the fault clearing information, the updated value of the fault clearing time of the relay protection device and retrofit location information of an electric power stabilizing device and control, based on the updated value of the fault clearing time, a corresponding relay protection device via a device control instruction to adjust a count of capacitors and types of the capacitors to be connected to a circuit, and issue an early warning notification of retrofitting the electric power stabilizing device to a user through the early warning device. More descriptions of this embodiment may be found in FIG. 2 and the related descriptions thereof.

In some embodiments, the voltage sag analysis device 120 may include a processor.

The processor may be configured to process data from at least one device or external data source of the control system 100. In some embodiments, the processor 110 may include a central processing unit (CPU), an application-specific integrated circuit (ASIC), an application-specific instruction set processor (ASIP), a physical computation unit (PPU), a digital signal processor (DSP), a microcontroller unit, a microprocessor, or any combination thereof.

The voltage sag data storage device 130 may be configured to store data, instructions, and/or any other information. For example, the voltage sag data storage device 130 may store the voltage sag data of the at least one different grid locations. As another example, the voltage sag data storage device 130 may store the historical fault information of the at least one different grid locations. As yet another example, the voltage sag data storage device 130 may store relay protection device information. As still another example, the voltage sag data storage device 130 may store historical fault clearing information.

In some embodiments, the voltage sag data storage device 130 may include a high-capacity storage device, a removable storage device, or any combination thereof.

The early warning device 140 may be configured to send information related to the operation of the transmission line in the power grid. For example, the early warning device may send the early warning notification for installing the electric power stabilizing device to the user. The user refers to a user corresponding to a power terminal device. The power terminal device refers to a device that operates using electrical power transmitted through the grid.

In some embodiments, the early warning device 140 may communicate with the power terminal device through the communication line.

In some embodiments, the early warning device 140 may be configured at the at least one different grid locations.

More descriptions of the power quality monitoring device 110, the voltage sag analysis device 120, the voltage sag data storage device 130, and the early warning device 140 may be found in FIG. 2 and the related descriptions thereof.

In some embodiments of the present disclosure, the system for controlling the multi-stage voltage sag effectively processes various electrical data and their features, clarifies the cause of the multi-stage voltage sag, and subsequently determines the updated value of the fault clearing time of the relay protection device and the retrofit information of the electric power stabilizing device, which can achieve intelligence of multi-stage voltage sag state control, and ensure stability of the power system.

FIG. 2 is a flowchart illustrating an exemplary process for controlling a multi-stage voltage sag according to some embodiments of the present disclosure. In some embodiments, a process 200 may be executed by the voltage sag analysis device 120. As shown in FIG. 2, the process 200 includes the following operations:

In 210, a power quality monitoring device may be controlled to read voltage sag data and fault clearing information based on an acquisition control instruction issued by the voltage sag analysis device and the voltage sag data may be sent to a power terminal device via a communication line.

The voltage sag data refers to data related to voltage fluctuations.

In some embodiments, the voltage sag data may include values of voltage rise/fall over multiple time periods at a location of a voltage monitoring device.

The fault clearing information refers to data related to a fault clearing action taken by a relay protection device and/or an electric power stabilizing device in response to a voltage sag occurring in a line. The fault clearing action refers to an operation such as isolating or disconnecting a fault component from a power system after a fault occurs in the power system. The fault component refers to a component that causes the voltage sag in the line, for example, a distributed generation device that trips during a short-circuit fault.

In some embodiments, the fault clearing information may include at least one of a fault clearing time, a fault duration, a fault starting time, and a fault ending time.

The fault clearing time refers to the duration from a start of the fault clearing action by the relay protection device and/or the electric power stabilizing device to a completion of fault clearing. The fault clearing refers to return of a line voltage magnitude to a standard range after the fault clearing action occurs. The standard range may be preset.

The fault duration refers to the duration from identifying the occurrence of the voltage sag in the line to fault clearing.

The fault starting time refers to a time when the voltage sag in the line is identified.

The fault ending time refers to a time when the fault is cleared.

The acquisition control instruction refers to an instruction used to control the power quality monitoring device to read data. In some embodiments, the acquisition control instruction may include at least one of a data reading cycle, a reading position sequence, and a reading type.

The data reading cycle refers to a time interval at which the power quality monitoring device reads data.

The reading position sequence refers to a sequence in which power quality monitoring devices at different grid locations read data.

The reading type refers to a mode in which the power quality monitoring device reads data. In some embodiments, the reading type may include continuous reading and intermittent reading. The continuous reading refers to continuously reading data at intervals of the data reading cycle, for example, reading data every 1 minute. The intermittent reading refers to reading data continuously at intervals of the data reading cycle after a preset duration, for a preset count of times. For example, reading data every 1 minute after every 10 minutes, for 5 consecutive readings. The preset duration and the preset count of times may be set in advance.

In some embodiments, the acquisition control instruction may be generated by the voltage sag analysis device based on historical fault information of different grid locations and sent to power quality monitoring devices located at the different grid locations.

In some embodiments, the historical fault information is stored in a voltage sag data storage device, and the voltage sag analysis device may retrieve the historical fault information of the different grid locations based on the voltage sag data storage device. The historical fault information refers to a count of occurrences of voltage sags at different grid locations over a historical period.

In some embodiments, the voltage sag analysis device may determine at least one of the data reading cycle, the reading position sequence, and the reading type for the power quality monitoring devices located at the different grid locations based on the historical fault information of the different grid locations, and generate the acquisition control instruction. In some embodiments, the voltage sag analysis device may determine the data reading cycle for the power quality monitoring device at a particular grid location based on a preset base cycle and a historical frequency of faults at the grid location. For example, a ratio of the preset base cycle to the historical frequency of faults may be determined as the data reading cycle. The historical frequency of faults may characterize the frequency of voltage sags at a grid location over a historical period. The preset base cycle refers to an initial data reading cycle and may be preset.

In some embodiments, the historical frequency of faults may be directly proportional to the count of voltage sag occurrences at the corresponding grid location. For example, the voltage sag analysis device may determine the historical frequency of faults for a grid location based on the count of voltage sag occurrences at the grid location using a preset formula, as shown in an equation (42):

$$O = {e}^{s / N} \qquad ( 42 )$$

Wherein Q represents the historical frequency of faults at the grid location, e denotes a natural constant, s denotes the count of voltage sag occurrences at the grid location, and N denotes a preset value. N may be preset.

In some embodiments, the voltage sag analysis device may determine the reading cycle based on the historical frequency of faults. In some embodiments, when the historical frequency of faults exceeds a frequency threshold, the voltage sag analysis device may determine the reading cycle as the continuous reading; when the historical frequency of faults does not exceed the frequency threshold, the voltage sag analysis device may determine the reading cycle as the intermittent reading. The frequency threshold may be preset.

It may be understood that the more frequent the occurrence of voltage sags at a grid location over a historical period, the more frequent the monitoring may be. Therefore, the shorter the data reading cycle and the more inclined towards continuous reading the reading cycle may be.

In some embodiments, the voltage sag analysis device may be configured to preliminarily sort the grid locations based on grid location levels, further sort a plurality of power quality monitoring devices corresponding to a plurality of grid locations within a same grid location level based on a historical fault frequency, and determine a assorting result of the plurality of power quality monitoring devices as the reading position sequence. For example, the higher the grid location level, the earlier the corresponding grid location is sorted. As another example, the higher the historical fault frequency, the earlier the power quality monitoring device is sorted. The plurality of grid locations with the same level may be sorted based on a sum of historical fault frequencies of the power quality monitoring devices corresponding to the plurality of grid locations within the same level. The higher the sum of the historical fault frequencies, the earlier the sorting of the grid location level.

The grid location levels may be predefined. For example, the higher an importance of a line where the grid location is located within the grid, the higher the grid location level. For example, based on the importance of the line within the grid, the line may be classified into a main line, a sub-main line, a branch line, and a branch sub-line, with the main line being the most important and the branch sub-line being the least important. Therefore, the grid location level of the main line is the highest and the grid location level of the branch sub-line is the lowest.

It may be understood that the higher the importance of the line where the grid location is located within the grid, the higher the priority for data collection may be, and consequently, the earlier the position is in the reading position sequence.

In some embodiments, the voltage sag analysis device may send the acquisition control instruction to the corresponding power quality monitoring device located at at least one different grid locations through the power terminal device.

In 220, a cause of the multi-stage voltage sag at the at least one different grid locations may be determined based on the voltage sag data of the at least one different grid locations obtained from the power terminal device.

The cause of the multi-stage voltage sag refers to a reason leading to the multi-stage voltage sag in the power system. In some embodiments, the cause of the multi-stage voltage sag may include a first cause and a second cause.

In some embodiments, the first cause refers to the tripping of one or more distributed generation devices in the power system during a short-circuit fault, resulting in a loss of power supply to the grid.

In some embodiments, the second cause refers to the tripping of relay protection devices on two sides of a fault line at different times during the short-circuit fault, leading to changes in grid topology. The fault line refers to the line experiencing a voltage sag.

In some embodiments, the voltage sag analysis device may be configured to determine the cause of the multi-stage voltage sag at the at least one different grid locations based on the voltage sag data in various ways. For example, the voltage sag analysis device may query a cause table based on the voltage sag data of the different grid locations to find a corresponding reference voltage sag cause, which is then determined as the cause of the multi-stage voltage sag at the at least one different grid locations.

The cause table may be predefined. In some embodiments, the cause table may include multiple sets of voltage sag data of the at least one different grid locations along with the corresponding reference voltage sag cause, which may include the first cause and/or the second cause. Each set of voltage sag data of the at least one different grid locations includes voltage sag data collected by a plurality of power quality monitoring devices located at different grid locations.

In some embodiments, the voltage sag analysis device may determine the cause of multi-stage voltage sag at the at least one different grid locations based on a correspondence between the cause of the multi-stage voltage sag and a voltage sag characteristic. The correspondence between the multi-stage voltage sag and the voltage sag characteristic may be obtained by pre-analysis. For example, a characteristic of a right-side voltage magnitude being smaller than a left-side voltage magnitude at an occurrence of a voltage sag may correspond to the first cause, while a characteristic of the right-side voltage magnitude being greater than the left-side voltage magnitude at an occurrence of a voltage sag may correspond to the second cause.

The voltage sag characteristic may represent the characteristic of the cause of the multi-stage voltage sag. In some embodiments, the voltage sag analysis device may determine the voltage sag characteristic based on the voltage sag data of the at least one different grid locations. For example, after the tripping of a distributed generation device, causing further power loss in the power system, the monitored voltage magnitude may decrease further. At this moment, if the right-side voltage magnitude at the voltage sag occurrence time is smaller than the left-side voltage magnitude, it indicates a voltage sag caused by the first cause. As another example, if a relay protection device on one side of a fault line isolates a fault component from the power system, causing an increase in the monitored voltage magnitude, then the occurrence time of the voltage sag corresponds to a voltage sag caused by the second cause when the right-side voltage magnitude is greater than the left-side voltage magnitude.

In some embodiments, the at least one different grid locations may include a voltage transient point. The voltage transient point refers to a point in the grid locations where the voltage sag exceeds a preset voltage threshold. The voltage threshold may be set in advance.

In some embodiments, the voltage sag analysis device may be configured to obtain a plurality of voltage transient points by detecting a voltage sag waveform using a preset detection process and divide the voltage sag waveform into a plurality of waveform segments based on the plurality of voltage transient points. The voltage sag analysis device may be further configured to determine a voltage value for each of the plurality of waveform segments based on a preset algorithm, construct a target vector based on voltage values of each of two adjacent waveform segments of the plurality of waveform segments, and determine, based on an element type of the target vector, the cause of the voltage sag at different transient points using a preset determination rule.

The voltage sag waveform refers to a waveform that represents changes in voltage values on the line.

In some embodiments, the voltage sag analysis device may detect the voltage sag waveform using the preset detection process to obtain the plurality of voltage transient points. The preset detection process may include a waveform point detection technique.

Waveform segments refer to waveforms between adjacent voltage transient points in the voltage sag waveform.

In some embodiments, the preset algorithm for determining the voltage values of the plurality of waveform segments may be set in advance. For example, in some embodiments, the preset algorithm may be represented by an equation (1):

$${u}_{m} = {\sum }_{j = ff * ( {t}_{m - 1} + \frac{1}{f} )}^{j = ff * {t}_{m}} {x}_{j} / ( ( {t}_{m} - {t}_{m - 1} + \frac{1}{f} ) * ff ) \qquad ( 1 )$$

Wherein ff denotes a sampling rate, f denotes a current frequency, xⱼ denotes a j-th value in a voltage value sequence, j is in a range of [1, k], wherein k denotes a count of sampling points, uₘ, denotes the voltage value of an m-th waveform segment, and m is in a range of [1, s]. The voltage value sequence refers to a sequence composed of voltage values obtained from a plurality of samples.

In some embodiments, the voltage sag analysis device may construct the target vector based on the voltage values of each of two adjacent waveform segments of the plurality of waveform segments using a preset construction rule. In some embodiments, the preset construction rule may be represented by an equation (2):

$$\{ \begin{matrix}W = [ {w}_{1} , {w}_{2} , … , {w}_{x} , … , {w}_{s} ] , x ∈ [ 1 , s ] \\ {w}_{x} = \{ \begin{matrix}0 , if {u}_{x} < {u}_{x - 1} or x = 1 \\ 1 , if {u}_{x} > {u}_{x - 1}\end{matrix}\end{matrix} \qquad ( 2 )$$

Wherein W represents the target vector, wₓ represents the vector element of an x-th waveform segment, and x>1. s+1 represents the count of transient points, and uₓ represents the voltage value of the x-th waveform segment. The x-th waveform segment refers to the waveform segment between an x+1th transient point and an x-th transient point.

The preset determination rule may be used to determine causes of the voltage sag at different transient points. The preset determination rule may be predefined. In some embodiments, the preset determination rule may include: when the vector element wₓ is 0, it indicates that the cause of the voltage sag at the corresponding transient point is the first cause; when the vector element wₓ is 1, it indicates that the cause of the voltage sag at the corresponding transient point is the second cause.

In some embodiments of the present disclosure, based on the target vector constructed from the voltage values of each adjacent two waveform segments, the voltage sag characteristic at the transient point can be intuitively understood, making it more convenient to determine the causes of the voltage sags at different transient points.

In 230, an updated value of a fault clearing time of a relay protection device and retrofit location information of an electric power stabilizing device may be determined based on the fault clearing information.

The updated value of the fault clearing time refers to the newly determined fault clearing time.

In some embodiments, the voltage sag analysis device may determine the updated value of the fault clearing time of the relay protection device based on the fault clearing information. For example, the voltage sag analysis device may extract the fault clearing time from the fault clearing information. In response to a determination that the fault clearing time exceeds a clearance threshold, the voltage sag analysis device may determine a redundant clearance duration. Then, based on a relationship between the redundant clearance duration and the updated value of the fault clearing time, the updated value may be determined. In response to a determination that the fault clearing time does not exceed the clearance threshold, the updated value remains the same as the original fault clearing time. The clearance threshold may be predefined. The redundant clearance duration refers to the duration when the fault clearing time exceeds the clearance threshold.

The correspondence between the redundant clearance duration and the updated value of the fault clearing time may be predefined. In some embodiments, the correspondence may include a negative correlation between the updated value of the fault clearing time and the redundant clearance duration. The longer the redundant clearance duration, the shorter the updated value of the fault clearing time.

In some embodiments, the voltage sag analysis device may determine the updated value of the fault clearing time based on a fault line and historical fault clearing information using a preset update algorithm. The historical fault clearing information refers to the fault clearing information corresponding to the fault line during a historical period. An exemplary preset update algorithm may be represented by an equation (42):

$$G = ( T1 * q 1 + … + T {n}^{⋆} q n ) \qquad ( 42 )$$

Wherein G represents the updated value of the fault clearing time, T1, . . . , Tn represent the fault clearing times of the fault line corresponding to different historical periods in the historical fault clearing information 1, . . . , n, respectively. q1, . . . , qn represent weights of the historical fault clearing information 1, . . . , n corresponding to the fault line, respectively. n denotes a count of pieces of historical fault clearing information corresponding to the fault line, and M denotes a count of weights after removing weights whose value is zero.

In some embodiments, the weights of the pieces of historical fault clearing information may be determined based on a device failure rate. In some embodiments, the weights of historical fault clearing information may be inversely proportional to the device failure rate of the corresponding relay protection devices. The higher the device failure rate, the smaller the weight. In response to the device failure rate associated with the fault clearing information being less than a predetermined threshold, the voltage sag analysis device may determine the weight of the historical fault clearing information corresponding to the fault lines as zero. The threshold for the device failure rate may be predefined.

The device failure rate may characterize the damage to the power terminal device after a voltage sag. In some embodiments, the voltage sag analysis device may determine the device failure rate by determining a ratio of a count of damaged power terminal devices after a voltage sag to a total count of power terminal devices. The count of the damaged power terminal devices and the total count of the power terminal devices may be input by a grid operator. More descriptions of the power terminal device and the grid operator may be found in the aforementioned relevant descriptions.

In some embodiments, the voltage sag analysis device may obtain the historical fault clearing information and the corresponding device failure rate from the voltage sag data storage device.

In some embodiments of the present disclosure, the historical fault clearing information occurring at different locations in the power grid can effectively reflect the operational reliability of the relay protection devices corresponding to the locations. The voltage sag analysis device processes the historical fault clearing information using the preset algorithm to determine the updated value of fault clearing time, which is more in line with actual situations and tailor the updated values differently for different locations in the power grid, thereby meeting requirements for grid stability.

In some embodiments, the voltage sag analysis device may adjust the updated value of the relay protection device based on the retrofit location information of the one or more electric power stabilizing devices. More descriptions of the retrofit location information may be found in the relevant descriptions below.

In some embodiments, in response to a determination that the retrofit location information includes a grid location where electric power stabilizing devices are not installed, the voltage sag analysis device may determine a ratio of the updated value of the fault clearing time of the relay protection device to a count of electric power stabilizing devices installed as the adjusted updated value of the relay protection device. The count of the electric power stabilizing devices refers to the quantity of electric power stabilizing devices installed at locations where they were not previously installed.

Adjusting the updated value of the relay protection device based on the retrofit location information of the electric power stabilizing device not only ensures grid stability and the safe and reliable operation of devices but also reduce operating costs.

The electric power stabilizing device is configured to maintain the stability of the power system.

The retrofit location information refers to information on a location where the electric power stabilizing device is installed.

In some embodiments, the voltage sag analysis device may determine a fault event type based on the fault clearing information and then determine the retrofit location information of the electric power stabilizing device based on the fault event type.

The fault event type refers to a specific fault event corresponding to the fault line and voltage sag types. For example, if on a fault line, a multi-stage voltage sag corresponding to a second type of voltage sag occurs, the fault event type may include the fault line and a short-circuit condition of the fault line, a time and a sequence of disconnection of distributed generation devices on the fault line. The disconnection of distributed generation devices refers to when the distributed generation devices are disconnect from the grid. As another example, if a multi-stage voltage sag corresponding to a first type of voltage sag occurs on a fault line, the fault event type may include the fault line and its short-circuit condition. As yet another example, for a multi-stage voltage sag corresponding to a third type of voltage sag, the fault event type may include the fault line and its short-circuit condition, a tripping time and a tripping sequence of the relay protection device. As still another example, for a multi-stage voltage sag corresponding to a fourth type of voltage sag, the fault event type may include the fault line and its short-circuit condition, the tripping time and the tripping sequence of the relay protection device, and a disconnection time and a disconnection sequence of the distributed generation device.

The voltage sag type refers to the type of the multi-stage voltage sag occurring on the fault line. In some embodiments, the voltage sag type may be predefined, including a first type, a second type, a third type, and a fourth type.

The first type may include a single-stage rectangular sag. The second type may include a multi-stage voltage sag caused by a first cause. The third type may include a multi-stage voltage sag caused by a second cause. The fourth type may include a multi-stage voltage sag caused by the first cause and the second cause.

In some embodiments, the voltage sag analysis device may determine at least one fault line based on the fault clearing information and determine the corresponding fault event type on the at least one fault line based on the voltage sag type.

In some embodiments, the voltage sag analysis device may determine, based on the fault clearing information, a line where the power quality monitoring device collecting the fault clearing information is located as the fault line.

In some embodiments, the voltage sag analysis device may determine the at least one fault line based on a protection action feature of at least one relay protection device at at least one grid location, the cause of voltage sag, and grid impedance information. More description of this embodiment may be found in FIG. 3 and its relevant description.

In some embodiments, the voltage sag analysis device may determine a related device experiencing voltage sag on the fault line based on the voltage sag type on the fault line and determine a fault condition of the related device based on data collected by the power quality monitoring device and determine the fault condition of the related device as the fault event type. The related device includes the relay protection device and the distributed generation device. The fault condition of the related device includes the tripping time and tripping sequence of the relay protection device and the disconnection time and disconnection sequence of the distributed generation device. The data collected by the power quality monitoring device includes the voltage sag data and the fault clearing information.

For example, if the voltage sag type on the fault line is the second type, the voltage sag analysis device may determine that the related device experiencing voltage sag on the fault line is a distributed generation device. Then, based on the data collected by the power quality monitoring device, the voltage sag analysis device may determine an occurrence time of the voltage sag as the disconnection time of the distributed generation device disconnected from the grid, and determine a sequence of different grid locations experiencing the voltage sag as the disconnection sequence. The disconnection time and the disconnection sequence of the distributed generation device are then determined as the fault event type corresponding to the fault line.

In some embodiments, after determining the fault event type corresponding to the multi-stage voltage sag occurring on the at least one fault line, the voltage sag analysis device may generate an early warning message based on the fault event type and issue the early warning message based on the early warning device located at the at least one different grid locations.

The early warning message refers to information notifying the grid operator about the fault event type on the fault line. In some embodiments, the early warning message may include a sound alarm, a text message alert, or the like. The sound alarm refers to the early warning device emitting sound to notify the grid operator to check the early warning device. The text message alert refers to the early warning device displaying the fault event type of the fault line in text format. The grid operator refers to personnel responsible for monitoring and managing the grid, such as a power engineer, etc.

In some embodiments, the voltage sag analysis device may determine the retrofit location information based on the fault clearing information. For example, the voltage sag analysis device may determine the grid locations where power quality devices have not been installed based on the fault clearing information.

In some embodiments, the voltage sag analysis device may obtain positional data of at least one fault line during a preset time period and construct a graph structure based on the positional data and the fault clearing information; and determine the retrofit location information using a location assessment model configured in the processor of the voltage sag analysis device. More descriptions on the fault clearing information may be found in the relevant descriptions above.

The positional data of the at least one fault line refers to the actual position of the at least one fault line in the grid. The preset time period may be predefined, for example, the past ten days.

In some embodiments, the voltage sag analysis device may obtain the positional data of the at least one fault line during the preset time period through the voltage sag data storage device. The voltage sag data storage device may obtain the positional data of the at least one fault line during the preset time period through user input or the like.

The graph structure may reflect a circuit relationship of fault lines. The graph structure is a data structure including a plurality of nodes and a plurality of edges, where the plurality of edges connect the plurality of nodes, and each of the plurality of nodes may have a node feature, and each of the plurality of edges may an edge feature.

In some embodiments, the plurality of nodes of the graph structure represent fault lines in the power grid. The node feature may include the positional data, historical fault information, and fault clearing information corresponding to the fault lines. More descriptions on the historical fault information may be found in the relevant descriptions above.

The plurality of edges of the graph structure may represent a circuit relationship between the plurality of nodes. The edge feature may include a supply line length, a supply voltage, or the like. In some embodiments, the edges of the graph structure may be directed, where a direction of the edge indicates a direction of a current flow.

In some embodiments, the voltage sag analysis device may construct the graph structure based on the circuit relationship of fault lines within the power grid, with the supply line length and the supply voltage as the edge feature. For example, the voltage sag analysis device may represent fault lines within the power grid as nodes in the graph structure and supply lines between fault lines as the edges in the graph structure, designate the positional data, the historical fault information, and the fault clearing information as the node feature, and designate the supply line length and the supply voltage as the edge feature to construct the graph structure.

In some embodiments, the plurality of nodes in the graph structure may also include a relay protection device node. The relay protection device node represents a relay protection device in the power grid, with the node feature being grid location information of the relay protection device. The grid location information of relay protection device refers to an actual position of the relay protection device in the power grid.

In some embodiments, the voltage sag analysis device may obtain the grid location information of the relay protection device through the voltage sag data storage device, which may obtain the grid location information through user input or other means.

In some embodiments of the present disclosure, including the relay protection device node in the graph structure makes the graph structure more reflective of real-world conditions, thereby improving the accuracy of an output of the location assessment model.

The location assessment model refers to a model configured to determine the retrofit location information. In some embodiments, the location assessment model may be a machine learning model. For example, the location assessment model may include any one of a graph neural network (GNN) model, a graph convolutional neural network (GCNN) model, or other custom model structures, or any combination thereof.

In some embodiments, an input of the location assessment model may include the graph structure, and an output of the location assessment model may include the retrofit location information. Specifically, a node output of the location assessment model corresponds to the retrofit location information. For example, the node output of the location assessment model may be 0 or 1, wherein 0 indicates that the corresponding grid location of the node does not require retrofitting of the electric power stabilizing device, and 1 indicates that the corresponding grid location of the node requires retrofitting of the electric power stabilizing device.

In some embodiments, the voltage sag analysis device may train the location assessment model based on a large number of second training samples labeled with second labels, employing techniques such as gradient descent. In some embodiments, the second training samples include sample graph structures. The sample graph structures may include historical graphs determined based on historical data, wherein nodes and node features and edges and edge features of the historical graphs are similar to the nodes and the node features and the edges and the edge features of the graph structure. The second labels may represent historical retrofit location information.

The historical retrofit location information refers to the retrofit location information corresponding to the historical graphs in the historical data. In some embodiments, the historical retrofit location information may be represented numerically by 1 and 0. When a node in the historical graph is labeled as 1, it indicates that the corresponding grid location of the node requires retrofitting of the electric power stabilizing device; when the node is labeled as 0, it indicates that the corresponding grid location of the node does not require retrofitting of the electric power stabilizing device.

In some embodiments, the second labels may be obtained through manual annotation. For example, when a relay protection device node in the historical graph fails, the historical retrofit location information corresponding to the node may be determined as 1. When the electric power stabilizing device was not retrofitted during a historical time period and subsequently, a fault line node reappears with the voltage sag leading to damage to the power terminal device, the historical retrofit location information corresponding to the node may be determined as 1.

In some embodiments of the present disclosure, the location assessment model configured in the processor of the voltage sag analysis device processes the graph structure to quickly and uniformly determine whether multiple locations in the grid need retrofitting of the electric power stabilizing device, significantly reducing computational load. The graph structure is constructed based on relevant data of the at least one fault line where faults occur in the grid and information related to the relay protection device, which conforms to real-world conditions and ensures the reliability of an output structure of the location assessment model.

In some embodiments, the voltage sag analysis device may determine magnitude data of the multi-stage voltage sag based on the fault event type and the fault clearing information, and determine the updated value of the fault clearing time and the retrofit location information based on the magnitude data, the at least one fault line, and the fault event type corresponding to the at least one fault line.

The magnitude data of the multi-stage voltage sag refers to a voltage sag magnitude of a bus line where the power quality monitoring device is not installed.

In some embodiments, the voltage sag analysis device may determine the magnitude data of the multi-stage voltage sag based on the fault event type and the fault clearing information in various ways. For example, the voltage sag analysis device may construct a vector to be matched based on the fault event type and the fault clearing information, match the vector to be matched against reference vectors in a vector database, and determine a voltage sag magnitude corresponding to a reference vector that meets a preset matching condition as the magnitude data of the multi-stage voltage sag. In some embodiments, the preset matching condition may include a vector distance being less than a distance threshold, wherein the vector distance may include a Euclidean distance, a cosine distance, or the like and the distance threshold may be set in advance.

In some embodiments, the vector to be matched may be constructed based on the fault event type, the fault clearing time, a fault duration, a fault starting time, and a fault ending time.

In some embodiments, the voltage sag analysis device may build the vector database based on historical data. The vector database may include a plurality of reference vectors and voltage sag magnitudes corresponding to the plurality of reference vectors. The reference vectors may include fault event types, fault clearing times, fault durations, fault starting times, and fault ending times in the historical data.

In some embodiments, the voltage sag analysis device may be further configured to predict, based on different voltage sag types, a voltage sag magnitude of any bus line that is not equipped with the power quality monitoring device by using different predictive equations.

In some embodiments, when the voltage sag type is the first type, the voltage sag analysis device may predict the voltage sag magnitude of the any bus line that is not equipped with the power quality monitoring device by using a first prediction equation. The first prediction equation may be represented by an equation (32):

$$u = f ( {g}_{m f 1} ( i , j , p ) , {g}_{f f 1} ( i , j , p ) ) ; \qquad ( 32 )$$

Wherein u denotes an estimated residual voltage, the function g_{mf1}(i,j,p) denotes a first mutual impedance between a fault location fₗ and a target node m when a short circuit fault occurs at the fault location fₗ at a distance p from a bus line i on the line lᵢⱼ, the function g_{ff1}(i,j,p) denotes a first self-impedance of the fault location fₗ when a short circuit fault occurs at the location fₗ at the distance p from the bus line i on the line lᵢⱼ, p denotes a normalized distance from a point f to the bus line i.

In some embodiments, when the voltage sag type is the second type, the voltage sag analysis device may predict the voltage sag magnitude of the any bus line not equipped with the power quality monitoring device by using a second prediction equation. The second prediction equation may be represented by an equation (33):

$$\{ \begin{matrix}{u}_{1} = f ( {g}_{m f 1} ( i , j , p ) , {g}_{f f 1} ( i , j , p ) ) \\ {u}_{x} = f ( {g}_{m f 3} ( i , j , p , {h}_{x - 1} ) , {g}_{f f 3} ( i , j , p , {h}_{x - 1} ) )\end{matrix} ; \qquad ( 33 )$$

Wherein u₁ denotes a residual voltage of a first stage, uₓ denotes a residual voltage of an x-th stage, the functions g_{mf3}(i,j,p,hₓ₋₁) and g_{ff3}(i,j,p,hₓ₋₁) denote a third mutual impedance between the fault location fₗ and the target node m and a third self-impedance of the fault location fₗ, respectively, when a short circuit fault occurs at the fault location fₗ at the distance p from the bus line i on the line lᵢⱼ and all distributed generation devices in a set of bus lines hₓ₋₁ are disconnected from a grid.

In some embodiments, when the voltage sag type is the second type, the voltage sag analysis device may predict the voltage sag magnitude of the any bus line not equipped with the power quality monitoring device by using a second prediction equation. The second prediction equation may be represented by an equation (34):

$$\{ \begin{matrix}{u}_{1} = f ( {g}_{m f 1} ( i , j , p ) , {g}_{f f 1} ( i , j , p ) ) \\ {u}_{2} = f ( {g}_{m f 2} ( i , j , p , d ) , {g}_{f f 2} ( i , j , p , d ) )\end{matrix} ; \qquad ( 34 )$$

Wherein, u₁ and u₂ denote the residual voltage of the first stage and a residual voltage of a second stage, respectively, the functions g_{mf2}(i,j,p,d) and g_{ff2}(i,j,p,d) denote, respectively, a second mutual impedance between the fault location fₗ and the target node m, and a second self-impedance of the fault location fₗ after a short circuit fault occurs at the fault location fₗ on the line lᵢⱼ at the distance p from the bus line i and a fault clearing action is performed by a protection device on a side of a line d.

In some embodiments, when the voltage sag type is the fourth type, the voltage sag analysis device may predict the voltage sag magnitude of the any bus line not equipped with the power quality monitoring device by using a fourth prediction equation. The fourth prediction equation may be represented by an equation (35):

$$\{ \begin{matrix}{u}_{1} = f ( {g}_{m f 1} ( i , j , p ) , {g}_{f f 1} ( i , j , p ) ) \\ {u}_{x} = f ( {g}_{m f 3} ( i , j , p , {h}_{x - 1} ) , {g}_{f f 3} ( i , j , p , {h}_{x - 1} ) ) \\ {u}_{y} = f ( {g}_{m f 2} ( i , j , p , d ) , {g}_{f f 2} ( i , j , p , d ) ) \\ {u}_{z} = f ( {g}_{m f 3} ( i , j , p , {h}_{z - 1} ) , {g}_{f f 3} ( i , j , p , {h}_{z - 1} ) ) \\ x ∈ [ 2 , y - 1 ] ; y ∈ [ y + 1 , s - 2 ]\end{matrix} ; \qquad ( 35 )$$

Wherein u₁, uₓ, u_{y}, and u_{z} denote the residual voltage of the first stage, the residual voltage of the x-th stage, a residual voltage of a y-th stage, and a residual voltage of a z-th stage, respectively, y and z denote the y-th stage and the z-th stage of the multi-stage voltage sag, respectively.

In some embodiments of the present disclosure, different types of prediction equations may be used to determine more accurately the voltage sag magnitude of the any bus line without the power quality monitoring device under different voltage sag types.

In some embodiments, the voltage sag analysis device may determine the updated value of fault clearing time in various ways based on the fault event type and magnitude data of the multi-stage voltage sag. For example, the voltage sag analysis device may determine, based on the fault event type, the relay protection device corresponding to the fault event type or the relay protection device corresponding to the distributed generation device. Then, based on a correspondence between the magnitude data of the multi-stage voltage sag and the updated value of the fault clearing time, the voltage sag analysis device may determine the updated value of the fault clearing time for the relay protection device mentioned above.

The correspondence between the magnitude data of the multi-stage voltage sag and the updated value of the fault clearing time may include a positive correlation between the updated value of the fault clearing time and the magnitude data of the multi-stage voltage sag. The larger the magnitude data, the shorter the updated value of fault clearing time. It may be understood that the larger the magnitude data of the multi-stage voltage sag, the greater an impact of the multi-stage voltage sag on the power system, the more inclined to quickly clear faults, and therefore, the shorter the updated value of the fault clearing time is.

In some embodiments, the voltage sag analysis device may determine the retrofit location information in various ways based on the fault event type and the magnitude data of the multi-stage voltage sag. For example, the voltage sag analysis device may determine, based on the fault event type, whether the relay protection device corresponding to the fault event type is malfunctioning. In response to determining that the relay protection device corresponding to the fault event type is malfunctioning, the voltage sag analysis device may determine that the retrofit location information includes the grid location of the malfunctioning relay protection device. As another example, the voltage sag analysis device may determine, based on the magnitude data of the multi-stage voltage sag, whether the magnitude data of the multi-stage voltage sag exceeds a magnitude threshold. In response to determining that the magnitude data of the multi-stage voltage sag exceeds a magnitude threshold, the voltage sag analysis device may determine that the retrofit location information includes the grid location where the power stabilizing device is not installed. The magnitude threshold may be set in advance. In some embodiments, the magnitude threshold may include at least one threshold corresponding to at least one different grid location levels, with each of the at least one threshold corresponding to a grid location level.

In 240, based on the updated value of the fault clearing time, a corresponding relay protection device may be controlled via a device control instruction to adjust a count of capacitors and types of the capacitors to be connected to a circuit, and an early warning notification of retrofitting the electric power stabilizing device may be issued to a user through the early warning device.

The device control instruction refers to an instruction used to control the adjustment of the count of the capacitors and the types of the capacitors to be connected to the circuit by the relay protection device. In some embodiments, the voltage sag analysis device may combine updated values of fault clearing times corresponding to different relay protection devices into the device control instruction and issue the device control instruction to the corresponding relay protection devices via the power terminal device to control the adjustment of the count of the capacitors and the types of the capacitors to be connected to the circuit. The relay protection device may automatically adjust the count of the capacitors and the types of the capacitors to be connected to the circuit based on the device control instruction.

The early warning notification refers to information reminding the user of the need to install the power stabilizing device in the power grid. More description of the user may be found in FIG. 1 and the related descriptions thereof. In some embodiments, the voltage sag analysis device may issue the early warning notification of retrofitting the electric power stabilizing device to a terminal device used by the user via the early warning device. The terminal device may include a mobile device, a tablet computer, a laptop, or the like.

In some embodiments, the early warning notification may include a short message notification. The short message notification may include a textual content of the retrofit location information sent by the early warning device.

In some embodiments of the present disclosure, based on the voltage sag data, the cause of the multi-stage voltage sag is determined, achieving rapid determination of the cause of the multi-stage voltage sag. Based on the cause of the multi-stage voltage sag, the updated value of the fault clearing time for the relay protection device and the retrofit location information for the electric power stabilizing device are determined. The early warning notification of retrofitting the electric power stabilizing device is issued to the user via the early warning device. This allows for quick adjustment or retrofitting of devices in the grid according to actual needs, thereby improving the stability of the grid and promptly notifying the user of information such as device installations.

FIG. 3 is a schematic diagram illustrating determining of at least one fault line and a fault event type corresponding to the at least one fault line according to some embodiments of the present disclosure.

As shown in FIG. 3, in some embodiments, a voltage sag analysis device (e.g., the voltage sag analysis device 120) may be configured to determine, based on fault clearing information 310, a protection action feature of a relay protection device at at least one grid location; determine a set of candidate fault lines 340 based on the protection action feature 320 and a cause 330 of a multi-stage voltage sag; obtain grid impedance information 350 through the power quality monitoring device 110; determine at least one fault line 370 and the fault event type 380 corresponding to a multi-stage voltage sag based on the set of candidate fault lines 340 and the grid impedance information 350 by using a fault processing model 360 configured in a processor of the voltage sag analysis device.

The protection action feature may characterize a feature of a fault clearing actions of the relay protection device. In some embodiments, the protection action feature may be represented by a vector or a matrix.

In some embodiments, the protection action feature may include an action matrix. The action matrix describes the fault clearing action of the relay protection device. Each row in the action matrix corresponds to fault clearing times of relay protection devices on two sides of a line, and each column in the action matrix corresponds to a line in a power system with two sides of the line connecting to two bus lines, respectively.

In some embodiments, the voltage sag analysis device may construct the basic action matrix based on the fault clearing time in the fault clearing information, decouple the basic action matrix into a first matrix and a second matrix, and construct a first similarity matrix and a second similarity matrix. The voltage sag analysis device may adjust the basic action matrix based on a coordination relationship between a main protection device and a backup protection device to obtain an adjusted action matrix, correct the fault clearing time in the adjusted action matrix based on a preset correction equation, and determine the corrected adjusted action matrix as the action matrix.

The basic action matrix refers to a generic matrix describing the fault clearing action of the relay protection device. The basic action matrix may be represented by an equation (3):

$$Γ = ( \begin{matrix}0 & {γ}_{12} & {γ}_{13} & … & {γ}_{1 n} \\ {γ}_{21} & 0 & {γ}_{23} & … & {γ}_{2 n} \\ {γ}_{31} & {γ}_{32} & 0 & ⋱ & ⋮ \\ ⋮ & ⋮ & ⋱ & 0 & {γ}_{( n - 1 ) n} \\ {γ}_{n 1} & {γ}_{n 2} & … & {γ}_{n ( n - 1 )} & 0\end{matrix} ) \qquad ( 3 )$$

Wherein n denotes a count of bus lines in the power system, γᵢⱼ denotes a fault clearing time of a relay protection device close to a bus line i on a line lᵢⱼ, γⱼᵢ denotes a fault clearing time of a relay protection device close to a bus line j on a line lᵢⱼ, the line lᵢⱼ denotes a line connecting the bus line i and the bus line j, a range of i and j is [1,n], i is not equal to j, and γᵢⱼ, γⱼᵢ=0 indicates no physical connection between the bus line i and the bus line j.

The first matrix represents the fault clearing time of the relay protection device close to the bus line i on the line lᵢⱼ, and the second matrix represents the fault clearing time of the relay protection device close to the bus line j on the line lᵢⱼ. The first matrix and the second matrix may be denoted by an equation (4) and an equation (5), respectively:

$$Γ \tilde{N} = ( \begin{matrix}0 & 0 & 0 & 0 & 0 \\ {γ}_{21} & 0 & 0 & 0 & 0 \\ {γ}_{31} & {γ}_{32} & 0 & 0 & 0 \\ ⋮ & ⋮ & ⋱ & 0 & 0 \\ {γ}_{n 1} & {γ}_{n 2} & … & {γ}_{n ( n - 1 )} & 0\end{matrix} ) ; \qquad ( 4 )$$

$$ΓΔ = ( \begin{matrix}0 & {γ}_{12} & {γ}_{13} & … & {γ}_{1 n} \\ 0 & 0 & {γ}_{23} & … & {γ}_{2 n} \\ 0 & 0 & 0 & ⋱ & ⋮ \\ 0 & 0 & 0 & 0 & {γ}_{( n - 1 ) n} \\ 0 & 0 & 0 & 0 & 0\end{matrix} ) ; \qquad ( 5 )$$

Wherein Γ\tilde{R} denotes the first matrix, a lower triangular element in the first matrix denotes the fault clearing time of the relay protection device close to the bus line i on the line lᵢⱼ, and when i>j, γᵢⱼ=0, γᵢⱼ=0 indicates no physical connection between the bus line i and the bus line j; ΓΔ denotes the second matrix, an upper triangular element in the second matrix denotes the fault clearing time of the relay protection device close to the bus line i on the line lᵢⱼ, and when i<j, γᵢⱼ=0.

In some embodiments, when a protection mode of the power system is two-stage protection, the relay protection device includes a main protection device and a backup protection device. The first matrix represents a fault clearing time of a main protection device close to the bus line i on the line lᵢⱼ, the second matrix represents a fault clearing time of a main protection device close to the bus line j on the line lᵢⱼ.

The first similarity matrix represents a fault clearing time of a backup protection device close to the bus line i on the line lᵢⱼ and the second matrix represents a fault clearing time of a backup protection device close to the bus line j on the line lᵢⱼ. The first similarity matrix and second similarity matrix may be denoted by an equation (6) and an equation (7), respectively:

$$Λ \tilde{N} = ( \begin{matrix}0 & 0 & 0 & 0 & 0 \\ {λ}_{21} & 0 & 0 & 0 & 0 \\ {λ}_{31} & {λ}_{32} & 0 & 0 & 0 \\ ⋮ & ⋮ & ⋱ & 0 & 0 \\ {λ}_{n 1} & {λ}_{n 2} & … & {λ}_{n ( n - 1 )} & 0\end{matrix} ) ; \qquad ( 6 )$$

$$ΛΔ = ( \begin{matrix}0 & {λ}_{12} & {λ}_{13} & … & {λ}_{1 n} \\ 0 & 0 & {λ}_{23} & … & {λ}_{2 n} \\ 0 & 0 & 0 & ⋱ & ⋮ \\ 0 & 0 & 0 & 0 & {λ}_{( n - 1 ) n} \\ 0 & 0 & 0 & 0 & 0\end{matrix} ) ; \qquad ( 7 )$$

Wherein ∧Ñ denotes the first similarity matrix, a lower triangular element in the first similarity matrix denotes the fault clearing time of the backup protection device close to the bus line i on the line lᵢⱼ, and when i>j, λᵢⱼ=0,λᵢⱼ=0 indicates no physical connection between bus line i and bus line j; ΛΔ denotes the second similarity matrix, an upper triangular element in the second similarity matrix element denotes the fault clearing time of the backup protection device close to the bus line j on the line lᵢⱼ and when i<j, λᵢⱼ=0.

In some embodiments, the adjusted action matrix is related to a cooperation relationship between the main protection device and the backup protection device. By way of example, the adjusted action matrix includes four types as denoted by an equation (8), an equation (9), an equation (10), and an equation (11):

$$Γ \tilde{N} + ΓΔ = {Θ}_{I} ; \qquad ( 8 )$$

$$Γ \tilde{N} + ΛΔ = {Θ}_{II} ; \qquad ( 9 )$$

$$Λ \tilde{N} + ΛΔ = {Θ}_{III} ; \qquad ( 10 )$$

$$Λ \tilde{N} + ΓΔ = {Θ}_{IV} ; \qquad ( 11 )$$

Wherein Θ_{I} denotes an adjusted action matrix indicating a relationship of main protection devices on two sides of a fault line cooperating with each other to clear a fault; Θ_{III} denotes an adjusted action matrix indicating a relationship of backup protection devices on two sides of the fault line cooperating with each other to clear the fault; Θ_{II} and Θ_{IV} denote an adjusted action matrix indicating a relationship of a main protection device on one side of the fault line and a backup protection device on the other side of the fault line cooperating with each other to clear the fault, respectively.

In some embodiments, the preset correction equation may be predetermined. For example, the preset correction equation may be represented by an equation (12):

$$\{ \begin{matrix}{γ}_{ij} = {γ}_{ij , set} + {δ}_{1 , ij} \\ {λ}_{ij} = {λ}_{ij , set} + {δ}_{2 , ij}\end{matrix} ; i , j ∈ [ 1 , n ] ; i \neq j ; \qquad ( 12 )$$

Wherein γ_{ij,set} and λ_{ij,set} denote setting values of the main protection device and the backup protection device, respectively, δ_{1,ij} denotes a deviation between an actual fault clearing time and the setting value γ_{ij,set} corresponding to the main protection device, δ_{2,ij} denotes a deviation between an actual fault clearing time and the setting value of λ_{ij,set} corresponding to the backup protection device, the deviation being a random number within [0,δ], and δ denotes a maximum error value of relay protection devices with a same type during a test process and/or a historical operation process. The setting values refer to the fault clearing times preset for the main protection device and the backup protection device.

Candidate fault lines refer to lines where voltage sags may occur. The set of candidate fault lines may include a plurality of candidate fault lines.

In some embodiments, the voltage sag analysis device may determine the set of candidate fault lines in various ways based on the protection action feature and the cause of the multi-stage voltage sag. For example, the voltage sag analysis device may determine, based on the protection action feature, the lines where relay protection devices with corresponding fault clearing times (non-zero) are located as the candidate fault lines. Based on the voltage sag type corresponding to the cause of the multi-stage voltage sag, the voltage sag analysis device may classify the candidate fault lines into different voltage sag types and determine the set of candidate fault lines.

In some embodiments, the voltage sag analysis device may determine the set of candidate fault lines based on the protection action feature by determining an action occurrence time sequence of the relay protection device at at least one grid location, determine potential fault levels for different candidate fault lines based on the action occurrence time sequence, and determine the set of candidate fault lines based on the potential fault levels.

The action occurrence time sequence refers to a sequence of action occurrence times. The action occurrence times refer to the times when the fault clearing action of the relay protection device occurs.

In some embodiments, the voltage sag analysis device may determine the fault clearing time of relay protection devices on the candidate fault lines based on the fault clearing time in the protection action feature and determine the fault starting time in the fault clearing information corresponding to the aforementioned fault clearing time. Then the voltage sag analysis device may determine, based on the fault starting time of the relay protection devices on the candidate fault lines, the potential fault levels of the candidate fault lines where the relay protection devices are located through a preset level relationship. The preset level relationship may be set in advance and the preset level relationship may include that the earlier the fault starting time is, the higher the potential fault level of the candidate fault line is.

In some embodiments, the voltage sag analysis device may determine the potential fault levels of the candidate fault lines through weighting.

In some embodiments, weights of the potential fault levels of the candidate fault lines may be related to the grid location level and the voltage sag type of the candidate fault lines. For example, the higher the grid location level and the more complex the voltage sag type (e.g., the fourth type being more complex than the second type and the third type), the greater a weight of a candidate fault line, and the higher the potential fault level of the candidate fault line.

In some embodiments, the voltage sag analysis device may add candidate fault lines with potential fault levels greater than a preset level threshold to the set of candidate fault lines based on the potential fault levels. The level threshold may be set in advance.

In some embodiments, the set of candidate fault lines may include the candidate fault lines and the potential fault levels corresponding to the candidate fault lines.

In some embodiments of the present disclosure, by determining the set of candidate fault lines based on the potential fault levels, candidate fault lines that are more likely to experience faults are included in the set of candidate fault lines, thereby facilitating more accurate determination of the fault lines.

In some embodiments, the voltage sag analysis device may determine a solution model based on the voltage sag type and determine the set of candidate fault lines based on the solution model and the protection action feature.

In some embodiments, in response to determining that the voltage sag type is the first type or the second type, the voltage sag analysis device may determine the solution model as a preset first solution model, the preset first solution model being represented by an equation (13):

$$\{ \begin{matrix}{LF}_{1} = \{ … , {l}_{ij} , … \} \\ s . t . {LF}_{1} ⊆ LN \\ \sqrt{\vert {θ}_{ij} - ( {t}_{s} - {t}_{0} ) \vert + \vert {θ}_{ji} - ( {t}_{s} - {t}_{0} ) \vert} \leq \\ \sqrt{max ( {δ}_{1 , ij} , {δ}_{1 , ji} ) + max ( {δ}_{2 , ij} , {δ}_{2 , ji} )} \leq \sqrt{2 δ} \\ i , j ∈ [ 1 , n ] ; i \neq j\end{matrix} ; \qquad ( 13 )$$

Wherein θᵢⱼ denotes an element of a j-th column in a i-th row of the adjusted action matrices Θ_{I}˜Θ_{IV}, LF1 denotes the first solution model, LN denotes a set of lines in a sag domain intersection, t₀ denotes a time corresponding to a first transient point in a voltage sag waveform and tₛ denotes a time corresponding to a last transient point in the voltage sag waveform.

In response to determining that the voltage sag type is the third or fourth type, the voltage sag analysis device may determine the solution model as a preset second solution model, the second solution model being represented by an equation (14):

$$\{ \begin{matrix}{LF}_{2} = \{ … , {l}_{ij} , … \} \\ s . t . {LF}_{2} ⊆ LN \\ \sqrt{\vert {θ}_{ij} - ( {t}_{x - 1} - {t}_{0} ) \vert + \vert {θ}_{ji} - ( {t}_{w} - {t}_{0} ) \vert} \leq \\ \sqrt{max ( {δ}_{1 , ij} , {δ}_{1 , ji} ) + max ( {δ}_{2 , ij} , {δ}_{2 , ji} )} \leq \sqrt{2 δ} \\ i , j ∈ [ 1 , n ] ; i \neq j ; s \geq 2 ; {w}_{x} = 1\end{matrix} ; \qquad ( 14 )$$

Wherein θᵢⱼ denotes an element of a j-th column in an i-th row of the adjusted action matrices Θ_{I}˜Θ_{IV}, LF2 denotes the second solution model, LN denotes the set of lines in the sag domain intersection, t₀ denotes the time corresponding to the first transient point in the voltage sag waveform, tₓ₋₁ denotes a time corresponding to an action of a relay protection device on one side of a fault line, and t_{w}, denotes a time corresponding to an action of a relay protection device on the other side of the fault line, and time durations from occurrence actions of a fault to protection actions of the relay protection devices on two sides of the fault line are denoted as tₓ₋₁-t₀ and t_{w}-t₀, respectively.

In some embodiments of the present disclosure, based on the voltage sag type, the solution model that better fits the actual situation may be determined, thereby establishing a more comprehensive and accurate set of candidate fault lines.

The grid impedance information refers to information related to the impedance in the power system. In some embodiments, the voltage sag analysis device may obtain the grid impedance information through the power quality monitoring device.

In some embodiments, the grid impedance information may include impedance information before and after the fault clearing time, impedance information at an activation time of the relay protection device, and impedance information at a disconnection time of a distributed power generation device disconnected from a grid.

In some embodiments, the impedance information before and after fault clearing time may include a first impedance matrix before a fault occurs and a second impedance matrix after the fault occurs.

In some embodiments, to determine the first impedance matrix, the voltage sag analysis device may be further configured to:

Calculate a line admittance matrix based on a line topology relationship and an impedance parameter, the line admittance matrix may be denoted by an equation (15):

$${Y}_{L}^{SE} = ( \begin{matrix}{α}_{11}^{se} & {α}_{12}^{se} & … & {α}_{1 n}^{se} \\ {α}_{21}^{se} & {α}_{22}^{se} & … & {α}_{2 n}^{se} \\ ⋮ & ⋮ & ⋱ & ⋮ \\ {α}_{n 1}^{se} & {α}_{n 2}^{se} & … & {α}_{nn}^{se}\end{matrix} ) ; \qquad ( 15 )$$

Wherein Y_{L}^{SE} denotes the line admittance matrix, αᵢⱼ denotes a mutual admittance between a node i configured to connect a line lᵢⱼ with a bus line i and a node j configured to connect the line lᵢⱼ with a bus line j, se=1 denotes a positive sequence, se=2 denotes a negative sequence, and se=0 denotes a zero sequence, αᵢᵢ denotes a self-admittance of a node configured to connect the bus line i with the line lᵢⱼ, i and j are in a range of [1,n], i is not equal to j, and n denotes a count of bus lines in the power system.

Determine, based on generator information, a generator admittance matrix. The generator admittance matrix may be denoted by an equation (16):

$${Y}_{G}^{SE} = ( \begin{matrix}{β}_{11}^{se} & 0 & … & 0 \\ 0 & {β}_{22}^{se} & … & 0 \\ ⋮ & ⋮ & ⋱ & ⋮ \\ 0 & 0 & … & {β}_{nn}^{se}\end{matrix} ) \qquad ( 16 )$$

Wherein Y_{G}^{SE} denotes a the generator admittance matrix, an element value βᵢᵢ on a diagonal denotes a self-admittance of the generator, se=1 denotes a positive sequence, se=2 denotes a negative sequence, se=0 denotes a zero sequence, and βᵢᵢ=0 indicates no generator at the bus line, i is in a range of [1,n] and n denotes the count of bus lines in the power system.

Determine the first impedance matrix based on the generator admittance matrix, the first impedance matrix may be determined by using an equation (17):

$${Z}_{N}^{SE} = {( {Y}_{G}^{SE} )}^{- 1} = ( \begin{matrix}{Z}_{11}^{se} & {Z}_{12}^{se} & … & {Z}_{1 n}^{se} \\ {Z}_{21}^{se} & {Z}_{22}^{se} & … & {Z}_{2 n}^{se} \\ ⋮ & ⋮ & ⋱ & ⋮ \\ {Z}_{n 1}^{se} & {Z}_{n 2}^{se} & … & {Z}_{nn}^{se}\end{matrix} ) \qquad ( 17 )$$

Wherein Y_{G}^{SE} denotes the generator admittance matrix and Z_{N}^{SE} denotes the first impedance matrix.

In some embodiments, the second impedance matrix may include the first mutual impedance between the fault location and the target node and the first self-impedance at the fault location. The fault location refers to the location where the voltage sag occurs.

In some embodiments, to determine the second impedance matrix, the voltage sag analysis device may be further configured to:

Calculate the first mutual impedance and the first self-impedance, wherein the first mutual impedance may be determined by using an equation (18) and the first self-impedance may be determined by using an equation (19), respectively:

$${Z}_{mf}^{se} = ( 1 - p ) {Z}_{mi}^{se} + {pZ}_{mj}^{se} = {g}_{mf 1} ( i , j , p ) \qquad ( 18 )$$

$${Z}_{ff}^{se} = \{ \begin{matrix}{( 1 - p )}^{2} {Z}_{ii}^{se} + {p}^{2} {Z}_{jj}^{se} \\ 2 p ( 1 - p ) {Z}_{ij}^{se} + p ( 1 - p ) {Z}_{ij}^{se}\end{matrix} \} = {g}_{ff 1} ( i , j , p ) \qquad ( 19 )$$

Wherein Zₘᵢ^{se}, Zₘⱼ^{se}, Zᵢⱼ^{se}, and Zⱼⱼ^{se} denote elements in the matrix Z_{N}^{SE} in the equation (17), zᵢⱼ^{se} denotes an impedance of the line lᵢⱼ, and the impedance is further represented by a function g_{mf1}(i,j,p) and a function g_{ff1}(i,j,p), the function g_{mf1}(i,j,p) denotes a first mutual impedance between a fault location fₗ and a target node m when a short circuit fault occurs at the fault location fₗ at a distance p from a bus line i on the line lᵢⱼ, the function g_{ff1}(i,j,p) denotes a first self-impedance of the fault location fₗ when the short circuit fault occurs at the fault location fₗ at the distance p from the bus line i on the line lᵢⱼ, p denotes a normalized distance from a point f to the bus line i.

In some embodiments, the impedance information at the activation time of the relay protection device includes a third impedance matrix when a relay protection action occurs on a single side of a fault line. The third impedance matrix may include the second mutual impedance between the fault location and the target node and the second self-impedance of the fault location when the relay protection action occurs on the single side of the fault line.

In some embodiments, to determine the third impedance matrix, the voltage sag analysis device may be further configured to:

Append a branch circuit between two bus lines of the power system and correct the first impedance matrix through a correction algorithm to obtain a first correction matrix, the correction algorithm is represented by an equation (20):

$${Z}_{AT}^{SE} = {Z}_{N}^{SE} - \frac{Δ Z Δ {Z}^{T}}{- {z}_{if}^{se} + {Z}_{ii}^{se} + {Z}_{jj}^{se} - 2 {Z}_{if}^{se}} = [ \begin{matrix}{Z}_{11 , AT}^{se} & {Z}_{12 , AT}^{se} & … & {Z}_{1 n , AT}^{se} \\ {Z}_{21 , AT}^{se} & {Z}_{22 , AT}^{se} & & {Z}_{2 n , AT}^{se} \\ ⋮ & & ⋱ & ⋮ \\ {Z}_{n 1 , AT}^{se} & {Z}_{n 2 , AT}^{se} & … & {Z}_{nn , AT}^{se}\end{matrix} ] \qquad ( 20 )$$

Wherein Z_{AT}^{SE} denotes the first correction matrix, ΔZ denotes a, which may be calculated by using an equation (21):

$$Δ Z = {[ \begin{matrix}{Z}_{1 j}^{se} - {Z}_{1 i}^{se} & {Z}_{2 j}^{se} - {Z}_{2 i}^{se} & … & {Z}_{nj}^{se} - {Z}_{ni}^{se}\end{matrix} ]}^{T} . \qquad ( 21 )$$

Append the other branch circuit at one of the two bus lines and correct the first correction matrix to obtain a second correction matrix. The second correction matrix may be represented by an equation (22):

$${Z}_{ARP}^{SE} = ( \begin{matrix}{Z}_{11 , AT}^{se} & {Z}_{12 , AT}^{se} & … & {Z}_{1 n , AT}^{se} & {Z}_{1 i , AT}^{se} \\ {Z}_{21 , AT}^{se} & {Z}_{22 , AT}^{se} & … & {Z}_{2 n , AT}^{se} & {Z}_{2 i , AT}^{se} \\ ⋮ & ⋮ & ⋱ & ⋮ & ⋮ \\ {Z}_{n 1 , AT}^{se} & {Z}_{n 2 , AT}^{se} & … & {Z}_{nn , AT}^{se} & {Z}_{ni , AT}^{se} \\ {Z}_{i 1 , AT}^{se} & {Z}_{i 2 , AT}^{se} & … & {Z}_{in , AT}^{se} & {Z}_{ii , AT}^{se} + {pz}_{ij}\end{matrix} ) \qquad ( 22 )$$

Wherein Z_{ARP}^{SE}, denotes the second correction matrix, one row and one column added to Z_{ARP}^{SE} compared to Z_{AT}^{SE} denote the second mutual impedance of the fault location fₗ with the respective target bus line m or the second self-impedance Z_{ff}^{se} of the fault location, and the second mutual impedance and the second self-impedance may be further represented by a function g_{mf2}(i,j,p,d) and a function g_{ff2}(i,j,p,d), respectively, the functions g_{mf2}(i,j,p,d) and g_{ff2}(i,j,p,d) represent, the second mutual impedance between the fault location fₗ and the target node m and the second self-impedance of the fault location fₗ after the short circuit fault occurs at the fault location fₗ at the distance p from the bus line i on the line lᵢⱼ and a fault clearing action is performed by a protection device on a side of a line d, respectively. The functions g_{mf2}(i,p,d) and g_{ff2}(i,j,p,d) may be represented by an equation (23) and an equation (24), respectively:

$${Z}_{mf}^{se} = {Z}_{im , AT}^{se} = {g}_{mf 2} ( i , j , p , d ) ; d = i or j \qquad ( 23 )$$

$${Z}_{ff}^{se} = {Z}_{ii , AT}^{se} + {pz}_{ij} = {g}_{ff 2} ( i , j , p , d ) ; d = i or j \qquad ( 24 )$$

In some embodiments, the impedance information at the disconnection time of the distributed power generation device disconnected from the grid may include a fourth impedance matrix when the distributed power generation device is disconnected from the grid. The fourth impedance matrix may include a third mutual impedance between the fault location and the target node and a third self-impedance of the fault location when the distributed power generation device is disconnected from the grid.

In some embodiments, to determine the fourth impedance matrix, the voltage sag analysis device may be further configured to:

Correct the generator admittance matrix to obtain a third correction matrix. The third correction matrix may be represented by an equation (25):

$${Y}_{G}^{SE ′} = ( \begin{matrix}{β}_{11}^{se} & 0 & … & 0 \\ 0 & {β}_{22}^{se} & … & 0 \\ ⋮ & ⋮ & ⋱ & ⋮ \\ 0 & 0 & … & {β}_{nn}^{se}\end{matrix} ) ; {β}_{ii}^{se} = 0 ; ∀ i ∈ h \qquad ( 25 )$$

Wherein, Y_{G}^{SE′} denotes the third correction matrix.

Update the first impedance matrix based on the third correction matrix to obtain the fourth impedance matrix. The fourth impedance matrix may be further represented by a function g_{mf3}(i,j,p,h) and a function g_{ff3}(i,j,p,h), the functions g_{mf3}(i,j,p,h) and g_{ff3}(i,j,p, h) denote the third mutual impedance between the fault location fₗ and the target node m and the third self-impedance of the fault location fₗ, respectively, when the short circuit fault occurs at the fault location fₗ at the distance p from the bus line i on the line lᵢⱼ and distributed power generation devices at all bus lines are disconnected from the grid. The functions g_{mf3}(i,j,p,h) and g_{ff3}(i,j,p,h) may be represented by an equation (26) and an equation (27), respectively:

$${Z}_{mf}^{se} = {g}_{mf 3} ( i , j , p , h ) \qquad ( 26 )$$

$${Z}_{ff}^{se} = {g}_{ff 3} ( i , j , p , h ) . \qquad ( 27 )$$

In some embodiments, different matrices are used to represent different grid impedance information, enabling a clear and intuitive understanding of the power system impedance information before and after the fault clearing time, the impedance information at the activation time of the relay protection device, and impedance information at the disconnection time of the distributed power generation device disconnected from the grid.

In some embodiments, the voltage sag analysis device may determine, based on a set of candidate fault lines and the grid impedance information, at least one fault line and the fault event type corresponding to the multi-stage voltage sag using a processing model configured in the processor of the voltage sag analysis device.

The processing model refers to an algorithmic rule used to determine the at least one fault line and the fault event type corresponding to the multi-stage voltage sag. In some embodiments, the processing model may include a fault processing model.

In some embodiments, the voltage sag analysis device may determine, based on the set of candidate fault lines and the grid impedance information, the at least one fault line and the fault event type corresponding to the multi-stage voltage sag using the fault processing model configured in the processor of the voltage sag analysis device. More descriptions of the set of candidate fault lines and the grid impedance information may be found in the above relevant descriptions.

In some embodiments, the processing model may include a fault processing model.

The fault processing model refers to a model used to determine the at least one fault line and the fault event type corresponding to the multi-stage voltage sag. In some embodiments, the fault processing model may be a machine learning model. For example, the fault processing model may include one of a recurrent neural network (RNN) model or other custom model structures, or any combination thereof.

In some embodiments, an input of the fault processing model may include the set of candidate fault lines and the grid impedance information, and an output of the fault processing model may include at least one fault line and the fault event type corresponding to the at least one fault line.

In some embodiments, the input of the fault processing model may further include relay protection device information.

The relay protection device information refers to information related to the relay protection device. In some embodiments, the relay protection device information may include the grid location and an operating parameter of the relay protection device, and a protected power terminal device. The operating parameter may include an action time, a rated voltage, etc. Wherein, the rated voltage refers to the voltage value that triggers the operation of the relay protection device.

In some embodiments, the voltage sag analysis device may obtain the relay protection device information through a voltage sag data storage device.

In some embodiments, the voltage sag analysis device may train the fault processing model based on a large number of first training samples labeled with first labels, using techniques such as gradient descent. In some embodiments, the first training samples may include sample sets of candidate fault lines and sample grid impedance information, and the first labels of the first training samples may be actual fault lines and fault event types corresponding to the actual fault lines. In some embodiments, when the input of the fault processing model includes the relay protection device information, the first training samples may also include sample relay protection device information. In some embodiments, the first training samples may be obtained based on historical data, and the first labels may be determined based on manual annotation.

By way of example, the voltage sag analysis device may input a plurality of first training samples labeled with a first label into an initial fault processing model, construct a loss function based on the first label and a predicted result of the initial fault processing model, and iteratively update the initial fault processing model based on the loss function. When the loss function of the initial fault processing model meets a preset condition, the training of the fault processing model is completed, wherein the preset condition may include convergence of the loss function, a count of iterations reaching a set value, etc.

In some embodiments, the voltage sag analysis device may construct a plurality of training sample sets based on a collection of historical candidate fault lines, historical grid impedance information, and grid location levels. More descriptions of the grid location levels may be found in the relevant descriptions above. The collection of historical candidate fault lines refer to a collection of candidate fault lines determined during a historical time period. The historical grid impedance information refers to impedance information determined during the historical time period.

In some embodiments, each of the plurality of training sample sets corresponds to a relay protection device and/or a distributed power generation device at a grid location with a different grid location level, respectively. The first training samples may include sample sets of candidate fault lines and sample grid impedance information, and the first labels of the first training samples may be actual fault lines and fault event types corresponding to the actual fault lines. The first labels may be determined based on manual annotation.

In some embodiments, the voltage sag analysis device may train the initial fault processing model separately based on training sample sets corresponding to the relay protection device, training sample sets corresponding to the distributed generation device, and training sample sets corresponding to both the relay protection device and the distributed generation device, respectively, to obtain the trained fault processing model.

In some embodiments of the present disclosure, by using the training sample sets corresponding to the relay protection device and/or the training sample sets corresponding to the distributed generation device, different types of training can be conducted on the initial fault processing model, thereby obtaining a more comprehensive fault processing model.

In some embodiments of this specification, by assigning different potential fault levels to different candidate fault lines based on grid location levels, the computational load of the processor configured in the voltage sag analysis device can be further reduced. By using the trained fault processing model embedded in the processor, it is possible to automatically and quickly determine the actual fault lines and corresponding specific fault events from a large number of candidate fault lines, thereby providing data support for timely determination of the need to replace relay protection devices and the locations where power stabilization devices need to be installed.

In some embodiments, the fault processing model may include an optimization model, which may be an algorithmic model. In some embodiments, the voltage sag analysis device may determine, using an optimization model, the at least one fault line and the fault event type corresponding to the multi-stage voltage sag based on the set of candidate fault lines and the grid impedance information. More descriptions of the protection action feature, the set of candidate fault lines, and the grid impedance information may be found in the relevant descriptions above.

The optimization model refers to a model configured to determine a fault line and the fault event type corresponding to the fault line. In some embodiments, the optimization model may include a plurality of types, and each type of the plurality of types of optimization model corresponds to a voltage sag type.

In some embodiments, the optimization model may include a first optimization model corresponding to the first type. The first optimization model is configured to infer a fault line and a short circuit situation of the fault line. The first optimization model may be represented by an equation (28):

$$\{ \begin{matrix}max - \sqrt{\vert f ( {g}_{mf 1} ( i , j , p ) , {g}_{ff 1} ( i , j , p ) ) \vert - {u}_{1}} \\ s . t . i , j ∈ [ 1 , n ] ; i \neq j\end{matrix} \qquad ( 28 )$$

Wherein f(⋅) denotes a function for short circuit calculation, the function g_{mf1}(i,j,p) denotes a first mutual impedance between a fault location fₗ and a target node m when a short circuit fault occurs at the fault location fₗ at a distance p from a bus line i on the line lᵢⱼ, the function g_{ff1}(i,j,p) denotes a first self-impedance of the fault location fₗ when the short-circuit fault occurs at the location fₗ at the distance p from bus line i on the line lᵢⱼ, p denotes a normalized distance from a point f to the bus line i.

In some embodiments, the optimization model may include a second optimization model corresponding to the second type. The second optimization model is configured to infer a fault line and a short circuit situation of the fault line, the disconnection time and a disconnection sequence of the distributed power generation device disconnected from the grid. The second optimization model may be represented by an equation (29):

$$\{ \begin{matrix}max - ( \begin{matrix}\sqrt{\vert f ( {g}_{mf 1} ( i , j , p ) , {g}_{ff 1} ( i , j , p ) \vert - {u}_{1}} + \\ {\sum }_{x = 2}^{s} {\sum }_{q = 1}^{s - 1} \sqrt{\vert f ( {g}_{mf 3} ( i , j , p , h ) , {g}_{ff 3} ( i , j , p , h ) ) \vert - {u}_{x}}\end{matrix} ) \\ s . t . i , j ∈ [ 1 , n ] ; i \neq j ; {h}_{1} ⊆ {h}_{2} ⊆ … ⊆ {h}_{s - 1}\end{matrix} ; \qquad ( 29 )$$

Wherein s denotes a count of stages of the multi-stage voltage sag, h_{q} denotes a set of distributed power generation devices disconnected from a grid during a q-th stage of the multi-stage voltage sag, and functions g_{mf3}(i,j,p, h_{q}) and g_{ff3}(i,j,p, h_{q}) denote a third mutual impedance between the fault location fₗ and the target node m and a third self-impedance of the fault location fₗ, respectively, when a short circuit fault occurs at the fault location fₗ at the distance p from the bus line i on the line lᵢⱼ and all distributed generation devices in the set h_{q} are disconnected from the grid.

In some embodiments, the optimization model may include a third optimization model corresponding to the third type, the third optimization model is configured to infer a fault line and a short circuit situation of the fault line, and a tripping time and a tripping sequence of the relay protection device. The third optimization model may be represented by an equation (30):

$$\{ \begin{matrix}max - ( \begin{matrix}\sqrt{\vert f ( {g}_{mf 1} ( i , j , p ) , {g}_{ff 1} ( i , j , p ) \vert - {u}_{1}} + \\ \sqrt{\vert f ( {g}_{mf 2} ( i , j , p , d ) , {g}_{ff 2} ( i , j , p , d ) ) \vert - {u}_{2}}\end{matrix} ) \\ s . t . i , j ∈ [ 1 , n ] ; i \neq j ;\end{matrix} ; \qquad ( 30 )$$

Wherein functions g_{mf2}(i,j,p,d) and g_{ff2}(i,j,p,d) denote a second mutual impedance between the fault location fₗ and the target node m and a second self-impedance of the fault location fₗ, respectively, after the short circuit fault occurs at the fault location fₗ at the distance p from the bus line i on the line lᵢⱼ and a fault clearing action is performed by a protection device on a side of a line d.

In some embodiments, the optimization model may include a fourth optimization model corresponding to the fourth type. The fourth optimization model may be configured to infer a fault line and a short circuit situation of the fault line, the tripping time and the tripping sequence of the relay protection device, and the disconnection time and the disconnection sequence of the distributed power generation device disconnected from the gird. The fourth optimization model may be represented by an equation (31):

$$\{ max - \begin{matrix}( \begin{matrix}\sqrt{\vert f ( {g}_{mf 1} ( i , j , p ) , {g}_{ff 1} ( i , j , p ) ) \vert - {u}_{1}} + \\ {\sum }_{x = 2}^{o} {\sum }_{q = 1}^{o = 1} \sqrt{\vert f ( {g}_{mf 3} ( i , j , p , {h}_{1} ) , {g}_{ff 3} ( i , j , p , {h}_{1} ) ) \vert - {u}_{x}} + \\ \sqrt{\vert f ( {g}_{mf 2} ( i , j , p , d ) , {g}_{ff 2} ( i , j , p , d ) ) \vert - {u}_{o + 1}} + \\ {\sum }_{x = o + 2}^{s} {\sum }_{q = 0}^{s - 2} \sqrt{\vert f ( {g}_{mf 3} ( i , j , p , {h}_{1} ) , {g}_{ff 3} ( i , j , p , {h}_{q} ) ) \vert - {u}_{x}}\end{matrix} ) \\ s . t . i , j ∈ [ 1 , n ] ; i \neq j ; {h}_{1} ⊆ {h}_{2} ⊆ … ⊆ {h}_{s - 2}\end{matrix} \qquad ( 31 )$$

Wherein o denotes a time when a relay protection device on one side of the fault line first trips and uₒ₊₁ denotes a voltage sag magnitude of a (o+1)-th stage.

In some embodiments of the present disclosure, different types of optimization models may be used to more accurately determine the fault lines corresponding to different types of voltage sags and the corresponding fault event type of the multi-stage voltage sag.

It should be noted that the descriptions of the process 200 above is merely exemplary and illustrative, and does not limit the scope of the present disclosure. Those skilled in the art may make various modifications and changes to the hand-eye calibration process under the guidance of the present disclosure. However, these modifications and changes are still within the scope of the present disclosure.

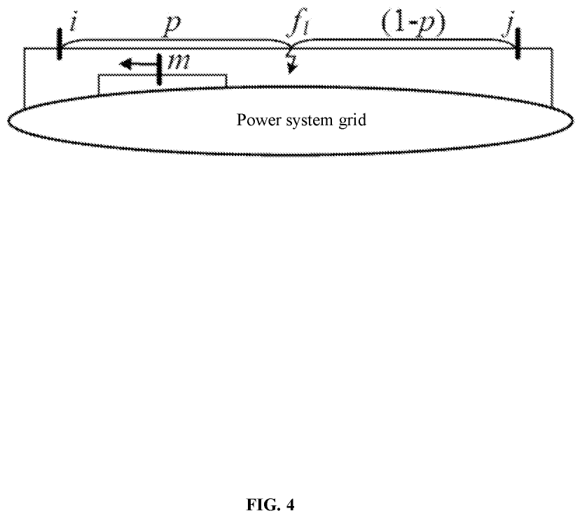

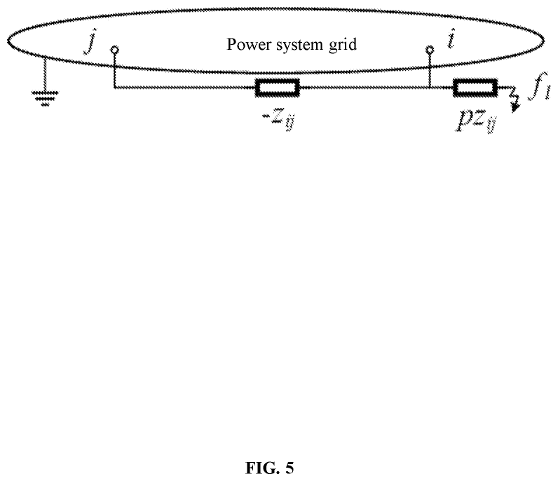

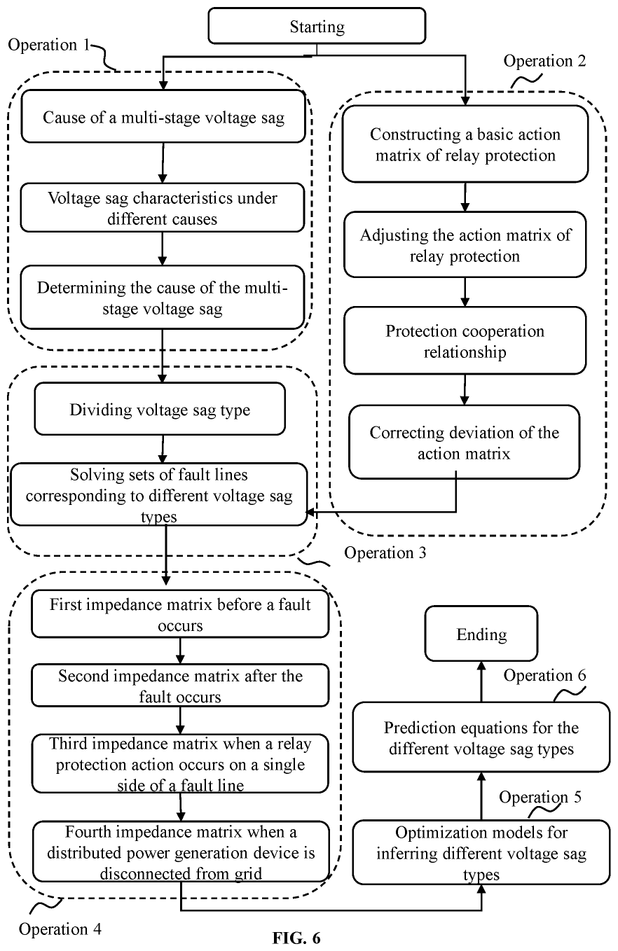

FIG. 4 is a schematic diagram illustrating a short-circuit calculation model according to some embodiments of the present disclosure; FIG. 5 is a schematic diagram illustrating a correction algorithm according to some embodiments of the present disclosure; and FIG. 6 is a flowchart illustrating an exemplary process for controlling a multi-stage voltage sag according to some embodiments of the present disclosure. FIGS. 4, 5, and 6 may be referred to understand some embodiments described below. However, the accompanying drawings and the descriptions of the drawings only serve as an illustration of some embodiments and do not constitute limitations on the embodiments.

Below is an embodiment of a method for controlling a multi-stage voltage sag, including the following operations: determining a cause of the multi-stage voltage sag, constructing an action matrix of a relay protection device, solving a set of fault lines, solving a first impedance matrix and a second impedance matrix, inferring fault event types, and controlling the multi-stage voltage sag. More descriptions of each operation and its sub-operations are as follows:

Operation 1, a cause of the multi-stage voltage sag may be determined. More descriptions on determining the cause of the multi-stage voltage sag may be found in FIG. 2 and the related descriptions thereof.

Operation 2, an action matrix of a relay protection device may be constructed. More descriptions on construction the action matrix of the relay protection device may be found in FIG. 2 and the related descriptions thereof.

Operation 3, a set of fault lines may be solved. More descriptions on solving the set of fault lines may be found in FIG. 2 and the related descriptions thereof.

Operation 4, a first impedance matrix and a second impedance matrix may be solved. More descriptions on solving the first impedance matrix and the second impedance matrix may be found in FIG. 2 and the related descriptions thereof.

Operation 5, fault event types may be inferred. More descriptions on inferring the fault event types may be found in FIG. 3 and the related descriptions thereof.

Operation 6, the multi-stage voltage sag may be controlled. More descriptions on controlling the multi-stage voltage sag may be found in FIG. 2 and the related descriptions thereof.

In some embodiments of the present disclosure, the characteristics of multi-stage sags caused by different causes are analyzed, considering the sudden transient time of each stage in the multi-stage sag monitoring data and the fault clearing time of the relay protection device, which allows inference of the specific events that may occur in each stage of the multi-stage voltage sag, ultimately leading to the method for controlling the multi-stage voltage sag that meets engineering requirements.

In some embodiments of the present disclosure, a non-transitory computer-readable storage medium. The storage medium stores one or more set of computer instructions, and when a computer reads the one or more set of computer instructions from the storage medium, the computer performs the method for controlling the multi-stage voltage sag described in the embodiments of the present disclosure.

Furthermore, certain features, structures, or characteristics in one or more embodiments of the present disclosure may be appropriately combined.

In some embodiments, the numbers expressing quantities or properties used to describe and claim certain embodiments of the application are to be understood as being modified in some instances by the term “about,” “approximate,” or “substantially.” For example, “about,” “approximate,” or “substantially” may indicate ±20% variation of the value it describes, unless otherwise stated. Accordingly, in some embodiments, the numerical parameters set forth in the written description and attached claims are approximations that may vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the application are approximations, the numerical values set forth in the specific examples are reported as precisely as practicable.

Should there be any inconsistency or conflict between the description, definition, and/or the use of a term associated with any of the incorporated material and that associated with the present document, the description, definition, and/or the use of the term in the present document shall prevail.

What is claimed is:

1. A system for controlling a multi-stage voltage sag, comprising a power quality monitoring device, a voltage sag analysis device, a voltage sag data storage device, and an early warning device, the voltage sag analysis device including a processor, wherein:
the power quality monitoring device is configured to read voltage sag data and fault clearing information based on an acquisition control instruction issued by the voltage sag analysis device and send the voltage sag data to a power terminal device via a communication line; the acquisition control instruction includes at least one of a data reading cycle, a reading position sequence, and a reading type; the communication line includes a power line carrier communication line, the fault clearing information includes at least one of a fault clearing time, a fault duration, a fault starting time, and a fault ending time, a count of the power quality monitoring device includes at least one, and the at least one power quality monitoring device is located at at least one different grid locations, respectively;
the voltage sag analysis device is configured to determine a cause of the multi-stage voltage sag of the at least one different grid locations based on the voltage sag data of the at least one different grid locations obtained from the power terminal device, and the voltage sag analysis device is further configured to:
obtain historical fault information of the at least one different grid locations based on the voltage sag data storage device;
determine the at least one of the data reading cycle, the reading position sequence, and the reading type of the power quality monitoring device located at the at least one different grid locations based on the historical fault information of the at least one different grid locations and generate the acquisition control instruction;
send the acquisition control instruction to the at least one power quality monitoring device located at the at least one different grid locations; and
the voltage sag analysis device is configured to determine, based on the fault clearing information, an updated value of a fault clearing time of a relay protection device and retrofit location information of an electric power stabilizing device and control, based on the updated value of the fault clearing time, a corresponding relay protection device via a device control instruction to adjust a count of capacitors and types of the capacitors to be connected to a circuit, and issue an early warning notification of retrofitting the electric power stabilizing device to a user through the early warning device.

2. The system of claim 1, wherein the voltage sag analysis device is configured to:
determine at least one fault line based on the fault clearing information;
determine, based on a voltage sag type, a fault event type corresponding to the multi-stage voltage sag occurring on the at least one fault line and generate an early warning message based on the fault event type; and
issue the early warning message based on the early warning device located at the at least one different grid locations.

3. The system of claim 1, wherein the voltage sag analysis device is configured to:
determine magnitude data of the multi-stage voltage sag based on the fault event type and the fault clearing information; and
determine the updated value of the fault clearing time and the retrofit location information based on the magnitude data, the at least one fault line, and the fault event type corresponding to the at least one fault line.

4. The system of claim 1, wherein the voltage sag analysis device is further configured to:
determine, based on the fault clearing information, a protection action feature of the relay protection device at least one grid location;
determine a set of candidate fault lines based on the protection action feature and the cause of the multi-stage voltage sag;
obtain grid impedance information through the power quality monitoring device, wherein the grid impedance information includes power system impedance information before and after the fault clearing time, impedance information at a activation time of the relay protection device, and impedance information at a disconnection time of a distributed power generation device disconnected from a grid; and
determine the at least one fault line and the fault event type corresponding to the multi-stage voltage sag based on the set of candidate fault lines and the grid impedance information by using a fault processing model configured in the processor of the voltage sag analysis device, the fault processing model being a machine learning model.

5. The system of claim 4, wherein model training of the fault processing model includes:
constructing a plurality of training sample sets based on a collection of historical candidate fault lines, historical grid impedance information, and grid location levels, wherein each of the plurality of training sample sets corresponds to a relay protection device and/or a distributed power generation device at a grid location with a different grid location level, respectively; and
training an initial fault processing model based on the plurality of training sample sets corresponding to relay protection devices and/or distributed power generation devices to obtain a trained fault processing model.

6. The system of claim 4, wherein the voltage sag analysis device is further configured to:
determine an action occurrence time sequence of the relay protection device located at the at least one grid location based on the protection action feature;
determine potential fault levels for different candidate fault lines based on the action occurrence time sequence; and
determine the set of candidate fault lines based on the potential fault levels.

7. The system of claim 1, wherein the voltage sag analysis device is further configured to:
obtain positional data of at least one fault line during a preset time period and construct a graph structure based on the positional data and the fault clearing information; and
determine the retrofit location information using a location assessment model configured in the processor of the voltage sag analysis device, the location assessment model being a machine learning model.

8. The system of claim 7, wherein the graph structure includes a plurality of nodes, the plurality of nodes are connected by a plurality of directed edges;
the plurality of nodes represent a plurality of fault lines, the plurality of directed edges represent circuit relationships between the plurality of fault lines;
a node feature of each of the plurality of nodes includes positional data, historical fault information, and the fault clearing information of each of the plurality of fault lines; and
an edge feature of each of the plurality of directed edges includes a supply line length and a supply voltage.

9. The system of claim 8, wherein the plurality of nodes further include a relay protection device node, and a node feature of the relay protection device node is grid location information of the relay protection device.

10. The system of claim 1, wherein to determine the updated value of the fault clearing time, the voltage sag analysis device is configured to:
determine the updated value of the fault clearing time based on the at least one fault line and historical fault clearing information using a preset update algorithm.

11. The system of claim 1, wherein the at least one different grid locations includes a voltage transient point, the voltage transient point includes a location point at which an amount of the voltage sag exceeds a voltage threshold, and the voltage sag analysis device is further configured to:
obtain a plurality of voltage transient points by detecting a voltage sag waveform using a preset detection process;
divide the voltage sag waveform into a plurality of waveform segments based on the plurality of voltage transient points;
determine a voltage value for each of the plurality of waveform segments based on a preset algorithm;
construct a target vector based on voltage values of each of two adjacent waveform segments of the plurality of waveform segments; and
determining, based on an element type of the target vector, the cause of the voltage sag at different transient points using a preset determination rule.

12. The system of claim 1, wherein the voltage sag analysis device is further configured to:
determine, based on the fault clearing information, a protection action feature of the relay protection device at least one grid location;
determine a set of candidate fault lines based on the protection action feature and the cause of the multi-stage voltage sag;
obtain, using the power quality monitoring device, grid impedance information, wherein the grid impedance information includes power system impedance information before and after the fault clearing time, impedance information at an activation time of the relay protection device, and impedance information at a disconnection time of a distributed power generation device disconnected from a grid; and
determine, using an optimization model, the at least one fault line and a fault event type corresponding to the multi-stage voltage sag based on the set of candidate fault lines and the grid impedance information.

13. The system of claim 12, wherein the protection action feature includes an action matrix, and the voltage sag analysis device is further configured to:
construct a basic action matrix, the basic action matrix being a generalized matrix describing a fault clearing action of the relay protection device, the basic action matrix is denoted by an equation (3):
$$Γ = ( \begin{matrix}0 & {γ}_{12} & {γ}_{13} & ⋯ & {γ}_{1 n} \\ {γ}_{21} & 0 & {γ}_{23} & ⋯ & {γ}_{2 n} \\ {γ}_{31} & {γ}_{32} & 0 & ⋱ & ⋮ \\ ⋮ & ⋮ & ⋱ & 0 & {γ}_{( n - 1 ) n} \\ {γ}_{n 1} & {γ}_{n 2} & ⋯ & {γ}_{n ( n - 1 )} & 0\end{matrix} ) ; \qquad ( 3 )$$
wherein n denotes a count of bus lines in a power system, γᵢⱼ denotes a fault clearing time of a relay protection device close to a bus line i on a line lᵢⱼ, γⱼᵢ, denotes a fault clearing time of a relay protection device close to a bus line j on a line lᵢⱼ, the line lᵢⱼ denotes a line connecting the bus line i and the bus line j, a range of i and j is [1,n], i is not equal to j, and γᵢⱼγⱼᵢ=0 indicates no physical connection between the bus line i and the bus line j;
decouple the basic action matrix into a first matrix and a second matrix, wherein the first matrix represents the fault clearing time of the relay protection device close to the bus line i on the line lᵢⱼ, and the second matrix represents the fault clearing time of the relay protection device close to the bus line j on the line lᵢⱼ, the first matrix and the second matrix are denoted by an equation (4) and an equation (5), respectively:
$$Γ \tilde{N} = ( \begin{matrix}0 & 0 & 0 & 0 & 0 \\ {γ}_{21} & 0 & 0 & 0 & 0 \\ {γ}_{31} & {γ}_{32} & 0 & 0 & 0 \\ ⋮ & ⋮ & ⋱ & 0 & 0 \\ {γ}_{n 1} & {γ}_{n 2} & ⋯ & {γ}_{n ( n - 1 )} & 0\end{matrix} ) ; \qquad ( 4 )$$
$$Γ Δ = ( \begin{matrix}0 & {γ}_{12} & {γ}_{13} & ⋯ & {γ}_{1 n} \\ 0 & 0 & {γ}_{23} & ⋯ & {γ}_{2 n} \\ 0 & 0 & 0 & ⋱ & ⋮ \\ 0 & 0 & 0 & 0 & {γ}_{( n - 1 ) n} \\ 0 & 0 & 0 & 0 & 0\end{matrix} ) ; \qquad ( 5 )$$
wherein ΓÑ denotes the first matrix, a lower triangular element in the first matrix denotes the fault clearing time of the relay protection device close to the bus line i on the line lᵢⱼ, and when i>j, γᵢⱼ=0, γᵢⱼ=0 indicates no physical connection between the bus line i and the bus line j; ΓΔ denotes the second matrix, an upper triangular element in the second matrix denotes the fault clearing time of the relay protection device close to the bus line i on the line lᵢⱼ, and when i<j, γᵢⱼ=0;
when a protection mode of the power system is two-stage protection, the relay protection device includes a main protection device and a backup protection device, the first matrix represents a fault clearing time of a main protection device close to the bus line i on the line lᵢⱼ, the second matrix represents a fault clearing time of a main protection device close to the bus line j on the line lᵢⱼ;
construct a first similarity matrix and a second similarity matrix, wherein the first similarity matrix represents a fault clearing time of a backup protection device close to the bus line i on the line lᵢⱼ and the second matrix represents a fault clearing time of a backup protection device close to the bus line j on the line lᵢⱼ, the first similarity matrix and second similarity matrix are denoted by an equation (6) and an equation (7), respectively:
$$Λ \tilde{N} = ( \begin{matrix}0 & 0 & 0 & 0 & 0 \\ {λ}_{21} & 0 & 0 & 0 & 0 \\ {λ}_{31} & {λ}_{32} & 0 & 0 & 0 \\ ⋮ & ⋮ & ⋱ & 0 & 0 \\ {λ}_{n 1} & {λ}_{n 2} & ⋯ & {λ}_{n ( n - 1 )} & 0\end{matrix} ) ; \qquad ( 6 )$$
$$ΛΔ = ( \begin{matrix}0 & {λ}_{12} & {λ}_{13} & ⋯ & {λ}_{1 n} \\ 0 & 0 & {λ}_{23} & ⋯ & {λ}_{2 n} \\ 0 & 0 & 0 & ⋱ & ⋮ \\ 0 & 0 & 0 & 0 & {λ}_{( n - 1 ) n} \\ 0 & 0 & 0 & 0 & 0\end{matrix} ) ; \qquad ( 7 )$$
wherein ΛÑ denotes the first similarity matrix, a lower triangular element in the first similarity matrix denotes the fault clearing time of the backup protection device close to the bus line i on the line lᵢⱼ, and when i>j, λᵢⱼ=0, λᵢⱼ=0 indicates no physical connection between bus line i and bus line j; ΛΔ denotes the second similarity matrix, an upper triangular element in the second similarity matrix element denotes the fault clearing time of the backup protection device close to the bus line j on the line lᵢⱼ and when i<j, λᵢⱼ=0;
adjust, based on a cooperation relationship between the main protection device and the backup protection device, the basic action matrix to obtain an adjusted action matrix, the adjusted action matrix including four types as denoted by an equation (8), an equation (9), an equation (10), and an equation (11):
$$Γ \tilde{N} + ΓΔ = {Θ}_{I} ; \qquad ( 8 )$$
$$Γ \tilde{N} + ΛΔ = {Θ}_{II} ; \qquad ( 9 )$$
$$Λ \tilde{N} + ΛΔ = {Θ}_{III} ; \qquad ( 10 )$$
$$Λ \tilde{N} + ΓΔ = {Θ}_{IV} ; \qquad ( 11 )$$
wherein Θ₁ denotes an adjusted action matrix indicating a relationship of main protection devices on two sides of a fault line cooperating with each other to clear a fault; Θ_{III} denotes an adjusted action matrix indicating a relationship of backup protection devices on two sides of the fault line cooperating with each other to clear the fault; Θ_{II} and Θ_{IV} denote an adjusted action matrix indicating a relationship of a main protection device on one side of the fault line and a backup protection device on the other side of the fault line cooperating with each other to clear the fault, respectively; and
correct the fault clearing time in the adjusted action matrix based on a preset correction equation, the preset correction equation is denoted by an equation (12):
$$\{ \begin{matrix}{γ}_{ij} = {γ}_{ij , set} + {δ}_{1 , ij} \\ {λ}_{ij} = {λ}_{ij , set} + {δ}_{2 , ij}\end{matrix} ; i , j ∈ [ 1 , n ] ; i \neq j \qquad ( 12 )$$
wherein γ_{ij,set} and λ_{ij,set} denote setting values of the main protection device and the backup protection device, respectively, δ_{1,ij} denotes a deviation between an actual fault clearing time and the setting value γ_{ij,set} corresponding to the main protection device, δ_{2,ij} denotes a deviation between an actual fault clearing time and the setting value of λ_{ij,set} corresponding to the backup protection device, the deviation being a random number within [0,δ], and δ denotes a maximum error value of relay protection devices with a same type during a test process and/or a historical operation process.

14. The system of claim 12, wherein the voltage sag type includes:
a first type, the first type including a single-stage rectangular sag;
a second type, the second type including a multi-stage voltage sag caused by a first cause;
a third type, the third type including a multi-stage voltage sag caused by a second cause; and
a fourth type, the fourth type including a multi-stage voltage sag caused by a combination of the first cause and the second cause;
the voltage sag analysis device is further configured to:
determine a solution model based on the voltage sag type; and
determine the set of candidate fault lines based on the solution model and the protection action feature.

15. The system of claim 14, wherein the voltage sag analysis device is further configured to:
in response to determining that the voltage sag type is the first type or the second type, determine the solution model as a preset first solution model, the first solution model being represented by an equation (13):
$$\{ \begin{matrix}L {F}_{1} = \{ … , {l}_{ij} , … \} \\ s . t . {L F}_{1} ⊆ LN \\ \sqrt{\vert {θ}_{ij} - ( {t}_{s} - {t}_{0} ) \vert + \vert {θ}_{j i} - ( {t}_{s} - {t}_{0} ) \vert} \leq \\ \sqrt{max ( {δ}_{1 , ij} , {δ}_{1 , ji} ) + max ( {δ}_{2 , ij} , {δ}_{2 , j i} )} \leq \sqrt{2 δ} \\ i , j ∈ [ 1 , n ] ; i \neq j\end{matrix} ; \qquad ( 13 )$$
wherein θᵢⱼ denotes an element of a j-th column in a i-th row of the adjusted action matrices Θ_{I}˜Θ_{IV}, LF1 denotes the first solution model, LN denotes a set of lines in a sag domain intersection, t₀ denotes a time corresponding to a first transient point in a voltage sag waveform and tₛ denotes a time corresponding to a last transient point in the voltage sag waveform;
in response to determining that the voltage sag type is the third type or the fourth type, determine the solution model as a preset second solution model, the second solution model being represented by an equation (14):
$$\{ \begin{matrix}{LF}_{2} = \{ … , {l}_{ij} , … \} \\ s . t . {LF}_{2} ⊆ LN \\ \sqrt{\vert {θ}_{ij} - ( {t}_{x - 1} - {t}_{0} ) \vert + \vert {θ}_{ji} - ( {t}_{w} - {t}_{0} ) \vert} \leq \\ \sqrt{max ( {δ}_{1 , ij} , {δ}_{1 , ji} ) + max ( {δ}_{2 , ij} , {δ}_{2 , j i} )} \leq \sqrt{2 δ} \\ i , j ∈ [ 1 , n ] ; i \neq j ; s \geq 2 ; {w}_{x} = 1\end{matrix} ; \qquad ( 14 )$$
wherein θᵢⱼ denotes an element of a j-th column in an i-th row of the adjusted action matrices Θ_{I}˜Θ_{IV}, LF2 denotes the second solution model, LN denotes the set of lines in the sag domain intersection, t₀ denotes the time corresponding to the first transient point in the voltage sag waveform, tₓ₋₁ denotes a time corresponding to an action of a relay protection device on one side of a fault line, and t_{w}, denotes a time corresponding to an action of a relay protection device on the other side of the fault line, and time durations from occurrence actions of a fault to protection actions of the relay protection devices on two sides of the fault line are denoted as tₓ₋₁-t₀ and t_{w}-t₀, respectively.

16. The system of claim 12, wherein
the power system impedance information before and after the fault clearing time includes a first impedance matrix before a fault occurs and a second impedance matrix after the fault occurs, and to determine the first impedance matrix, the voltage sag analysis device is further configured to:
calculate a line admittance matrix based on a line topology relationship and an impedance parameter, the line admittance matrix is denoted by an equation (15):
$${Y}_{L}^{SE} = ( \begin{matrix}{α}_{11}^{se} & {α}_{12}^{se} & ⋯ & {α}_{1 n}^{se} \\ {α}_{21}^{se} & {α}_{22}^{se} & ⋯ & {α}_{2 n}^{se} \\ ⋮ & ⋮ & ⋱ & ⋮ \\ {α}_{n 1}^{se} & {α}_{n 2}^{se} & ⋯ & {α}_{nn}^{se}\end{matrix} ) \qquad ( 15 )$$
wherein γ_{L}^{SE} denotes the line admittance matrix, αᵢⱼ denotes a mutual admittance between a node i configured to connect a line lᵢⱼ with a bus line i and a node j configured to connect the line lᵢⱼ with a bus line j, se=1 denotes a positive sequence, se=2 denotes a negative sequence, and se=0 denotes a zero sequence, αᵢᵢ denotes a self-admittance of a node configured to connect the bus line i with the line lᵢⱼ, i and j are in a range of [1,n], i is not equal to j, and n denotes a count of bus lines in the power system;
determine, based on generator information, a generator admittance matrix, the generator admittance matrix is denoted by an equation (16):
$${y}_{G}^{{SE}_{=}} ( \begin{matrix}{β}_{11}^{se} & 0 & ⋯ & 0 \\ 0 & {β}_{22}^{se} & ⋯ & 0 \\ ⋮ & ⋮ & ⋱ & ⋮ \\ 0 & 0 & ⋯ & {β}_{nn}^{se}\end{matrix} ) ; \qquad ( 16 )$$
wherein, γ_{G}^{SE} denotes the generator admittance matrix, an element value βᵢᵢ on a diagonal denotes a self-admittance of the generator, se=1 denotes a positive sequence, se=2 denotes a negative sequence, se=0 denotes a zero sequence, and βᵢᵢ=0 indicates no generator at the bus line, i is in a range of [1,n] and n denotes the count of bus lines in the power system;
determine the first impedance matrix based on the generator admittance matrix, the first impedance matrix is determined by using an equation (17):
$${Z}_{N}^{SE} = {( {Y}_{G}^{SE} )}^{- 1} = ( \begin{matrix}{Z}_{11}^{se} & {Z}_{12}^{se} & ⋯ & {Z}_{1 n}^{se} \\ {Z}_{21}^{se} & {Z}_{22}^{se} & ⋯ & {Z}_{2 n}^{se} \\ ⋮ & ⋮ & ⋱ & ⋮ \\ {Z}_{n 1}^{se} & {Z}_{n 2}^{se} & ⋯ & {Z}_{nn}^{se}\end{matrix} ) ; \qquad ( 17 )$$
wherein γ_{G}^{SE} denotes the generator admittance matrix and Z_{N}^{SE} denotes the first impedance matrix; and
the second impedance matrix includes a first mutual impedance between a fault location and a target node after the fault occurs and a first self-impedance of the fault location, and to determine the second impedance matrix, the voltage sag analysis device is further configured to:
calculate the first mutual impedance and the first self-impedance, the first mutual impedance is determined by using an equation (18) and the first self-impedance is determined by using an equation (19), respectively:
$${Z}_{mf}^{se} = ( 1 - p ) {Z}_{m i}^{s e} + p {Z}_{mj}^{s e} = {g}_{mf 1} ( i , j , p ) ; \qquad ( 18 )$$
$${Z}_{ff}^{s e} = \{ \begin{matrix}{( 1 - p )}^{2} {Z}_{ii}^{s e} + {p}^{2} {Z}_{jj}^{s e} \\ 2 p ( 1 - p ) {Z}_{i j}^{s e} + p ( 1 - p ) {Z}_{i j}^{s e}\end{matrix} \} = {g}_{ff 1} ( i , j , p ) ; \qquad ( 19 )$$
wherein Zₘᵢ^{se}, Zₘⱼ^{se}, Zᵢⱼ^{se}, Zᵢᵢ^{se}, and Zⱼⱼ^{se} denote elements in the matrix Z_{N}^{SE} in the equation (17), zᵢⱼ^{se} denotes an impedance of the line lᵢⱼ, and the impedance is further represented by a function g_{mf1}(i,j,p) and a function g_{ff1}(i,j,p), the function g_{mf1}(i,j,p) denotes a first mutual impedance between a fault location fₗ and a target node m when a short circuit fault occurs at the fault location fₗ at a distance p from a bus line i on the line lᵢⱼ, the function g_{ff1}(i,j,p) denotes a first self-impedance of the fault location fi when the short circuit fault occurs at the fault location fₗ at the distance p from the bus line i on the line lᵢⱼ, p denotes a normalized distance from a point f to the bus line i; and
the impedance information at the activation time of the relay protection device includes a third impedance matrix when a relay protection action occurs on a single side of a fault line, the third impedance matrix includes a second mutual impedance between the fault location and the target node and a second self-impedance of the fault location when the relay protection action occurs on the single side of the fault line, and to determine the third impedance matrix, the voltage sag analysis device is further configured to:
append a branch circuit between two bus lines of the power system and correct the first impedance matrix through a correction algorithm to obtain a first correction matrix, the correction algorithm is represented by an equation (20):
$${Z}_{A T}^{SE} = {Z}_{N}^{SE} - \frac{Δ Z Δ {Z}^{T}}{- {z}_{if}^{s e} + {Z}_{ii}^{s e} + {Z}_{jj}^{s e} - 2 {Z}_{if}^{s e}} = [ \begin{matrix}{Z}_{11 , AT}^{se} & {Z}_{12 , AT}^{se} & … & {Z}_{1 n , AT}^{se} \\ {Z}_{21 , AT}^{se} & {Z}_{22 , AT}^{se} & & {Z}_{2 n , AT}^{se} \\ ⋮ & & ⋱ & ⋮ \\ {Z}_{n 1 , AT}^{se} & {Z}_{n 2 , AT}^{se} & … & {Z}_{nn , AT}^{se}\end{matrix} ] ; \qquad ( 20 )$$
wherein Z_{AT}^{SE} denotes the first correction matrix and ΔZ denotes a process quantity, which is calculated by using an equation (21):
$$Δ Z = {[ {Z}_{1 j}^{s e} - {Z}_{1 i}^{s e} {Z}_{2 j}^{s e} - {Z}_{2 i}^{s e} … {Z}_{n j}^{s e} - {Z}_{n i}^{s e} ]}^{T} ; \qquad ( 21 )$$
append the other branch circuit at one of the two bus lines and correct the first correction matrix to obtain a second correction matrix, the second correction matrix is represented by an equation (22):
$${Z}_{ARP}^{SE} = ( \begin{matrix}{Z}_{11 , AT}^{se} & {Z}_{12 , AT}^{se} & … & {Z}_{1 n , AT}^{se} & {Z}_{1 i , AT}^{se} \\ {Z}_{21 , AT}^{se} & {Z}_{22 , AT}^{se} & … & {Z}_{2 n , AT}^{se} & {Z}_{2 i , AT}^{se} \\ ⋮ & ⋮ & ⋱ & ⋮ & ⋮ \\ {Z}_{n 1 , AT}^{se} & {Z}_{n 2 , AT}^{se} & … & {Z}_{nn , AT}^{se} & {Z}_{ni , AT}^{se} \\ {Z}_{i 1 , AT}^{se} & {Z}_{i 2 , AT}^{se} & … & {Z}_{i n , AT}^{se} & {Z}_{ii , AT}^{se} + {pz}_{ij}\end{matrix} ) ; \qquad ( 22 )$$
wherein Z_{ARP}^{SE} denotes the second correction matrix, one row and one column added to Z_{ARP}^{SE}, compared to Z_{AT}^{SE} denote the second mutual impedance Z_{mf}^{se} of the fault location fₗ with the respective target bus line m or the second self-impedance Z_{ff}^{se} of the fault location, and the second mutual impedance and the second self-impedance are further represented by a function g_{mf2}(i,j,p,d) and a function g_{ff2}(i,j,p,d), respectively, the functions g_{mf2}(i,j,p,d) and g_{ff2}(i,j,p,d) represent, the second mutual impedance between the fault location fₗ and the target node m and the second self-impedance of the fault location fₗ after the short circuit fault occurs at the fault location fₗ at the distance p from the bus line i on the line lᵢⱼ and a fault clearing action is performed by a protection device on a side of a line d, respectively, the functions g_{mf2}(i,j,p,d) and g_{ff2} (i,j,p,d) are represented by an equation (23) and an equation (24), respectively:
$${Z}_{mf}^{s e} = {Z}_{im , AT}^{s e} = {g}_{mf 2} ( i , j , p , d ) ; d = i or j ; \qquad ( 23 )$$
$${Z}_{ff}^{s e} = {Z}_{ii , AT}^{s e} + p {z}_{i j} = {g}_{ff2} ( i , j , p , d ) ; d = i or j ; \qquad ( 24 )$$
the impedance information at the disconnection time of the distributed power generation device disconnected from the grid includes a fourth impedance matrix when the distributed power generation device is disconnected from the grid, the fourth impedance matrix includes a third mutual impedance between the fault location and the target node and a third self-impedance of the fault location when the distributed power generation device is disconnected from the grid, and to determine the fourth impedance matrix, the voltage sag analysis device is further configured to:
correct the generator admittance matrix to obtain a third correction matrix, the third correction matrix is represented by an equation (25):
$${y}_{G}^{SE ′} = ( \begin{matrix}{β}_{11}^{s e} & 0 & … & 0 \\ 0 & {β}_{22}^{s e} & … & 0 \\ ⋮ & ⋮ & ⋱ & ⋮ \\ 0 & 0 & … & {β}_{nn}^{s e}\end{matrix} ) ; {β}_{i i}^{s e} = 0 ; ∀ i ∈ h \qquad ( 25 )$$
wherein, Y_{G}^{SE′} denotes the third correction matrix;
update the first impedance matrix based on the third correction matrix to obtain the fourth impedance matrix, the fourth impedance matrix is further represented by a function g_{mf3}(i,j,p,h) and a function g_{ff3}(i,j,p,h), the functions g_{mf3}(i,j,p,h) and g_{ff3}(i,j,p,h) denote the third mutual impedance between the fault location fₗ and the target node m and the third self-impedance of the fault location fₗ, respectively, when the short circuit fault occurs at the fault location fₗ at the distance p from the bus line i on the line lᵢⱼ and distributed power generation devices at all bus lines are disconnected from the grid, the functions g_{mf3}(i,j,p,h) and g_{ff3}(i,j,p,h) are represented by an equation (26) and an equation (27), respectively:
$${Z}_{mf}^{s e} = {g}_{mf 3} ( i , j , p , h ) ; \qquad ( 26 )$$
$${Z}_{ff}^{s e} = {g}_{ff 3} ( i , j , p , h ) . \qquad ( 27 )$$

17. The system of claim 12, wherein the optimization model includes a plurality of types, and each type of the plurality of types of optimization model corresponds to a voltage sag type, wherein,
the optimization model includes a first optimization model corresponding to a first type, the first optimization model is configured to infer a fault line and a short circuit situation of the fault line, and the first optimization model is represented by an equation (28):
$$\{ \begin{matrix}max - \sqrt{\vert f ( {g}_{mf 1} ( i , j , p ) , {g}_{ff 1} ( i , j , p ) ) \vert - {u}_{1}} \\ s . t . i , j ∈ [ 1 , n ] ; i \neq j\end{matrix} ; \qquad ( 28 )$$
wherein f(⋅) denotes a function for short circuit calculation, the function g_{mf1}(i,j,p) denotes a first mutual impedance between a fault location fₗ and a target node m when a short circuit fault occurs at the fault location fₗ at a distance p from a bus line i on the line lᵢⱼ, the function g_{ff1}(i,j,p) denotes a first self-impedance of the fault location fₗ when the short-circuit fault occurs at the location fₗ at the distance p from bus line i on the line lᵢⱼ, p denotes a normalized distance from a point f to the bus line i;
the optimization model includes a second optimization model corresponding to a second type, the second optimization model is configured to infer a fault line and a short circuit situation of the fault line, the disconnection time and a disconnection sequence of the distributed power generation device disconnected from the grid, and the second optimization model is represented by an equation (29):
$$\{ \begin{matrix}max - ( \begin{matrix}\sqrt{\vert f ( {g}_{mf 1} ( i , j , p ) , {g}_{ff 1} ( i , j , p ) ) \vert - {u}_{1}} + \\ {\sum }_{x = 2}^{s} {\sum }_{q = 1}^{s - 1} \sqrt{\vert f ( {g}_{mf 3} ( i , j , p , h ) , {g}_{ff 3} ( i , j , p , h ) ) \vert - {u}_{x}}\end{matrix} ) \\ s . t . i , j ∈ [ 1 , n ] ; i \neq j ; {h}_{1} ⊆ {h}_{2} ⊆ … ⊆ {h}_{s - 1}\end{matrix} ; \qquad ( 29 )$$
wherein s denotes a count of stages of the multi-stage voltage sag, h_{q} denotes a set of distributed power generation devices disconnected from a grid during a q-th stage of the multi-stage voltage sag, and functions g_{mf3}(i,j,p,h_{q}) and g_{ff3}(i,j,p,h_{q}) denote a third mutual impedance between the fault location fₗ and the target node m and a third self-impedance of the fault location fₗ, respectively, when a short circuit fault occurs at the fault location fₗ at the distance p from the bus line i on the line lᵢⱼ and all distributed generation devices in the set h_{q} are disconnected from the grid;
the optimization model includes a third optimization model corresponding to a third type, the third optimization model is configured to infer a fault line and a short circuit situation of the fault line, and a tripping time and a tripping sequence of the relay protection device, and the third optimization model is represented by an equation (30):
$$\{ \begin{matrix}max - ( \begin{matrix}\sqrt{\vert f ( {g}_{mf 1} ( i , j , p ) , {g}_{ff 1} ( i , j , p ) ) \vert - {u}_{1}} + \\ \sqrt{\vert f ( {g}_{mf 2} ( i , j , p , d ) , {g}_{ff 2} ( i , j , p , d ) ) \vert - {u}_{2}}\end{matrix} ) \\ s . t . i , j ∈ [ 1 , n ] ; i \neq j ;\end{matrix} ; \qquad ( 30 )$$
wherein functions g_{mf2}(i,j,p,d) and g_{ff2}(i,j,p,d) denote a second mutual impedance between the fault location fₗ and the target node m and a second self-impedance of the fault location fₗ, respectively, after the short circuit fault occurs at the fault location fₗ at the distance p from the bus line i on the line lᵢⱼ and a fault clearing action is performed by a protection device on a side of a line d; and
the optimization model includes a fourth optimization model corresponding to a fourth type, the fourth optimization model is configured to infer a fault line and a short circuit situation of the fault line, the tripping time and the tripping sequence of the relay protection device, and the disconnection time and the disconnection sequence of the distributed power generation device disconnected from the gird, the fourth optimization model is represented by an equation (31):
$$\{ \begin{matrix}max - ( \begin{matrix}\sqrt{\vert f ( {g}_{mf 1} ( i , j , p ) , {g}_{ff 1} ( i , j , p ) ) \vert - {u}_{1}} + \\ {\sum }_{x = 2}^{o} {\sum }_{q = 1}^{o - 1} \sqrt{\vert f ( {g}_{mf 3} ( i , j , p , {h}_{q} ) , {g}_{ff 3} ( i , j , p , {h}_{q} ) ) \vert - {u}_{x}} + \\ \vert f ( {g}_{mf 2} ( i , j , p , d ) , {g}_{ff 2} ( i , j , p , d ) ) \vert - {u}_{o + 1} + \\ {\sum }_{x = o + 2}^{s} {\sum }_{q = 1}^{s - 1} \sqrt{\vert f ( {g}_{mf 3} ( i , j , p , {h}_{q} ) , {g}_{ff 3} ( i , j , p , {h}_{q} ) ) \vert - {u}_{x}}\end{matrix} ) \\ s . t . i , j ∈ [ 1 , n ] ; i \neq j ; {h}_{1} ⊆ {h}_{2} ⊆ … ⊆ {h}_{s - 2}\end{matrix} \text{} ; \qquad ( 31 )$$
wherein o denotes a time when a relay protection device on one side of the fault line first trips and u₀₊₁ denotes a voltage sag magnitude of a (o+1)-th stage.

18. The system of claim 3, wherein the magnitude data includes a multi-stage voltage sag magnitude and the voltage sag analysis device is further configured to predict, based on different voltage sag types, a voltage sag magnitude of any bus line that is not equipped with the power quality monitoring device by using different predictive equations, wherein,
when the voltage sag type is a first type, the voltage sag magnitude of the any bus line not equipped with the power quality monitoring device is predicted by using a first prediction equation, the first prediction equation is represented by an equation (32):
$$u = f ( {g}_{mf 1} ( i , j , p ) , {g}_{ff 1} ( i , j , p ) ) ; \qquad ( 32 )$$
Wherein u denotes an estimated residual voltage, the function g_{mf1}(i,j,p) denotes a first mutual impedance between a fault location fₗ and a target node m when a short circuit fault occurs at the fault location fₗ at a distance p from a bus line i on the line lᵢⱼ, the function g_{ff1}(i,j,p) denotes a first self-impedance of the fault location fₗ when the short circuit fault occurs at the location fₗ at the distance p from the bus line i on the line lᵢⱼ, p denotes a normalized distance from a point f to the bus line i;
when the voltage sag type is a second type, the voltage sag magnitude of the any bus line not equipped with the power quality monitoring device is predicted by using a second prediction equation, the second prediction equation is represented by an equation (33):
$$\{ \begin{matrix}{u}_{1} = f ( {g}_{m f 1} ( i , j , p ) , {g}_{ff 1} ( i , j , p ) ) \\ {u}_{x} = f ( {g}_{mf 3} ( i , j , p , {h}_{x - 1} ) , {g}_{ff 3} ( i , j , p , {h}_{x - 1} ) )\end{matrix} ; \qquad ( 33 )$$
wherein u₁ denotes a residual voltage of a first stage, uₓ denotes a residual voltage of an x-th stage, the functions g_{mf3}(i,j,p,hₓ₋₁) and g_{ff3}(i,j,p,hₓ₋₁) denote a third mutual impedance between the fault location fₗ and the target node m and a third self-impedance of the fault location fₗ, respectively, when a short circuit fault occurs at the fault location fₗ at the distance p from the bus line i on the line lᵢⱼ and all distributed generation devices in a set of bus lines hₓ₋₁ are disconnected from a grid;
when the voltage sag type is a third type, the voltage sag magnitude of the any bus line not equipped with the power quality monitoring device is predicted by using a third prediction equation, the third prediction equation is represented by an equation (34):
$$\{ \begin{matrix}{u}_{1} = f ( {g}_{mf 1} ( i , j , p ) , {g}_{ff 1} ( i , j , p ) ) \\ {u}_{2} = f ( {g}_{mf 2} ( i , j , p , d ) , {g}_{ff 2} ( i , j , p , d ) )\end{matrix} ; \qquad ( 34 )$$
wherein, u₁ and u₂ denote the residual voltage of the first stage and a residual voltage of a second stage, respectively, the functions g_{mf2}(i,j,p,d) and g_{ff2}(i,j,p,d) denote, respectively, a second mutual impedance between the fault location fₗ and the target node m, and a second self-impedance of the fault location fₗ after a short circuit fault occurs at the fault location fₗ on the line lᵢⱼ at the distance p from the bus line i and a fault clearing action is performed by a protection device on a side of a line d; and
when the voltage sag type is a fourth type, the voltage sag magnitude of the any bus line not equipped with the power quality monitoring device is predicted using a fourth prediction equation, the fourth prediction equation is represented by an equation (35):
$$\{ \begin{matrix}{u}_{1} = f ( {g}_{m f 1} ( i , j , p ) , {g}_{ff 1} ( i , j , p ) ) \\ = f ( {g}_{mf 3} ( i , j , p , {h}_{x - 1} ) , {g}_{ff 3} ( i , j , p , {h}_{x - 1} ) ) \\ {u}_{y} = f ( {g}_{mf 2} ( i , j , p , d ) , {g}_{ff 2} ( i , j , p , d ) ) \\ {u}_{z} = f ( {g}_{mf 3} ( i , j , p , {h}_{z - 1} ) , {g}_{ff 3} ( i , j , p , {h}_{z - 1} ) ) \\ x ∈ [ 2 , y - 1 ] ; y ∈ [ y + 1 , s - 2 ]\end{matrix} ; \qquad ( 35 )$$
wherein u₁, uₓ, u_{y}, and u_{z} denote the residual voltage of the first stage, the residual voltage of the x-th stage, a residual voltage of a y-th stage, and a residual voltage of a z-th stage, respectively, y and z denote the y-th stage and the z-th stage of the multi-stage voltage sag, respectively.

19. A method for controlling a multi-stage voltage sag, wherein the method is performed by a voltage sag analysis device and the method comprises:
controlling, based on an acquisition control instruction, a power quality monitoring device to read voltage sag data and fault clearing information, wherein the acquisition control instruction includes at least one of a data reading cycle, a reading position sequence, and a reading type, a communication line includes at least a power line carrier communication line, the fault clearing information includes at least one of a fault clearing time, a fault duration, a fault starting time, and a fault ending time, a count of the power quality monitoring device includes at least one, and the at least one power quality monitoring device is located at at least one different grid locations, respectively, the acquisition control instruction is generated by the voltage sag analysis device based on historical fault information of the at least one different grid locations and sent to the power quality monitoring device located at the at least one different grid locations, and the historical fault information is stored in a voltage sag data storage device;
determining a cause of the multi-stage voltage sag of the at least one different grid locations based on the voltage sag data of the at least one different grid locations obtained from a power terminal device;
determining, based on the fault clearing information, an updated value of the fault clearing time of a relay protection device and retrofit location information of an electric power stabilizing device and controlling, based on the updated value of the fault clearing time, a corresponding relay protection device via a device control instruction to adjust a count of capacitors and types of the capacitors to be connected to a circuit, and issuing an early warning notification of retrofitting the electric power stabilizing device to a user through an early warning device.

20. A non-transitory computer-readable storage medium, wherein the storage medium stores one or more set of computer instructions, and when a computer reads the one or more set of computer instructions from the storage medium, the computer performs a method for controlling a multi-stage voltage sag of claim 19.
